(19) United States
(12) Patent Application Publication
(10) Pub. No.: US 2026/0333679 A1
(43) Pub. Date: Oct. 22, 2026

(54) BODY CONTACT BETWEEN MULTIPLEXERS AND STORAGE NODE REGIONS ON VERTICAL THREE DIMENSIONAL (3D) MEMORY

(71) Applicant: Micron Technology, Inc., Boise, ID (US)

(72) Inventors: Kamal M. Karda, Boise, ID (US); Si-Woo Lee, Saratoga, CA (US); Aniket Gupta, Hillsboro, OR (US); Haitao Liu, Boise, ID (US)

(21) Appl. No.: 19/651,001

(22) Filed: Apr. 17, 2026

Related U.S. Application Data
(60) Provisional application No. 63/790,927, filed on Apr. 18, 2025.

(51) Int. Cl. H10B 12/00; H10W 20/41

(52) U.S. Cl. CPC H10B 12/50; H10B 12/05; H10B 12/482; H10B 12/485; H10B 12/488; H10W 20/435

(57) ABSTRACT

Systems, methods, and apparatus are provided for forming vertical three dimensional (3D) memory with multiplexers. An array of vertically stacked memory cells can include horizontally oriented access devices and storage nodes and a multiplexer device formed on the array of vertically stacked memory cells. The multiplexer device can include a conductive contact coupled to a body region of the multiplexer device between a first source/drain region of the multiplexer device and a storage node region of the array of vertically stacked memory cells. A local digit line coupled to the first source/drain region of the multiplexer device and to the access devices of the array of vertically stack memory cells. A global digit line can be coupled to a second source/drain region of the multiplexer device and to logic components for accessing the array of vertically stacked memory cells.

### PRIORITY INFORMATION

This application claims the benefit of U.S. Provisional Application No. 63/790,927, filed on Apr. 18, 2025, the contents of which are incorporated herein by reference.

### TECHNICAL FIELD

The present disclosure relates generally to memory devices, and more particularly, to memory devices including body contacts between multiplexers and storage node regions on vertical three dimensional (3D) memory.

### BACKGROUND

Memory is often implemented in electronic systems, such as computers, cell phones, hand-held devices, etc. There are many different types of memory, including volatile and non-volatile memory. Volatile memory may require power to maintain its data and may include random-access memory (RAM), dynamic random-access memory (DRAM), static random-access memory (SRAM), and synchronous dynamic random-access memory (SDRAM). Non-volatile memory may provide persistent data by retaining stored data when not powered and may include NAND flash memory, NOR flash memory, nitride read only memory (NROM), phase-change memory (e.g., phase-change random access memory), resistive memory (e.g., resistive random-access memory), cross-point memory, ferroelectric random-access memory (FeRAM), or the like.

As design rules shrink, less semiconductor space is available to fabricate memory, including DRAM arrays. A respective memory cell for DRAM may include an access device, e.g., transistor, having a first and a second source/drain regions separated by epitaxially grown channel regions. A gate may oppose the channel region and be separated therefrom by a gate dielectric. An access line, such as a word line, is electrically connected to the gate of the DRAM cell. A DRAM cell can include a storage node, such as a capacitor cell, coupled by the access device to a digit line. The access device can be activated (e.g., to select the cell) by an access line coupled to the access transistor. The capacitor can store a charge corresponding to a data value of a respective cell (e.g., a logic “1” or “0”).

### BRIEF DESCRIPTION OF THE DRAWINGS

FIG. 1A is a schematic illustration of a horizontal access device in a vertical three-dimensional (3D) memory in accordance a number of embodiments of the present disclosure.

FIG. 1B is a perspective view illustrating a portion of a horizontal access device in vertical three-dimensional (3D) memory in accordance with a number of embodiments of the present disclosure.

FIG. 2 illustrates a portion of a horizontal access device in vertical three-dimensional (3D) memory in accordance with a number of embodiments of the present disclosure.

FIG. 3 is a schematic illustration of a vertical three dimensional (3D) memory in functional association with logic components for the 3D memory array.

FIG. 4 illustrates a portion of a vertical three-dimensional (3D) memory with a multiplexer in accordance with a number of embodiments of the present disclosure.

FIG. 5 is a cross-sectional view, at one stage of a semiconductor fabrication process, for vertical three-dimensional (3D) memory with a multiplexer, in accordance with a number of embodiments of the present disclosure.

FIGS. 6A to 6B illustrate an example method, at one stage of a semiconductor fabrication process, for vertical three-dimensional (3D) memory with a multiplexer, in accordance with a number of embodiments of the present disclosure.

FIGS. 7A to 7D illustrate an example method, at another stage of a semiconductor fabrication process, for vertical three-dimensional (3D) memory with a multiplexer, in accordance with a number of embodiments of the present disclosure.

FIGS. 8A to 8B illustrate an example method, at another stage of a semiconductor fabrication process, for vertical three-dimensional (3D) memory with a multiplexer, in accordance with a number of embodiments of the present disclosure.

FIG. 9 illustrates an example method, at another stage of a semiconductor fabrication process, for vertical three-dimensional (3D) memory with a multiplexer, in accordance with a number of embodiments of the present disclosure.

FIGS. 10A to 10C illustrate an example method, at another stage of a semiconductor fabrication process, for vertical three-dimensional (3D) memory with a multiplexer, in accordance with a number of embodiments of the present disclosure.

FIGS. 11A to 11B illustrate an example method, at another stage of a semiconductor fabrication process, for vertical three-dimensional (3D) memory with a multiplexer, in accordance with a number of embodiments of the present disclosure.

FIG. 12 is a block diagram of an apparatus in the form of a computing system including a memory device in accordance with a number of embodiments of the present disclosure.

### DETAILED DESCRIPTION

Embodiments of the present disclosure describe forming multiplexers on a vertical stack including three dimensional (3D) memory. A multiplexer device or devices are formed on (e.g., over the uppermost levels/tiers) of an array of vertically stacked memory cells. The multiplexer device can be coupled to a global digit line via a global digit line contact that allows the memory cells in the vertical stack of memory cells to be accessed. Forming the multiplexer device on the array of vertically stacked memory cells can eliminate the need to form additional multiplexer circuitry on other portions of the wafer which can reduce the footprint and cost when forming the array of memory cells. The multiplexer device can be formed using the process flow of forming an access device.

The multiplexer device can be formed with a conductive contact coupled to a body region of the multiplexer device. The conductive contact can be coupled to a voltage source to provide a voltage potential to bias the multiplexer device and reduce and/or eliminate floating body effects (FBE). The conductive contact can be coupled to a voltage source to provide a voltage potential to bias the multiplexer device and control the threshold voltage for activating and/or deactivating the multiplexer device. The conductive contact can be coupled to a voltage source to provide a voltage potential to bias the multiplexer device and reduce and/or eliminate plate disturb from the upper electrode of the storage nodes in the array of memory cells. The multiplexer device can be a multiplexer, a demultiplexer, a multiplexer/demultiplexer, and/or a bleeder device in various embodiments of the present disclosure. The multiplexer device can be an access device that allows circuitry (e.g., logic circuitry) coupled to the multiplexer to sense, write, and/or access memory cells in the memory array.

The of vertically stacked memory cells can include horizontally oriented access devices and storage nodes and a multiplexer device formed on the array of vertically stacked memory cells. The multiplexer device can include a conductive contact coupled to a body region of the multiplexer device between a first source/drain region of the multiplexer device and a storage node region of the array of vertically stacked memory cells. A local digit line coupled to the first source/drain region of the multiplexer device and to the access devices of the array of vertically stack memory cells. A global digit line can be coupled to a second source/drain region of the multiplexer device and to logic components for accessing the array of vertically stacked memory cells.

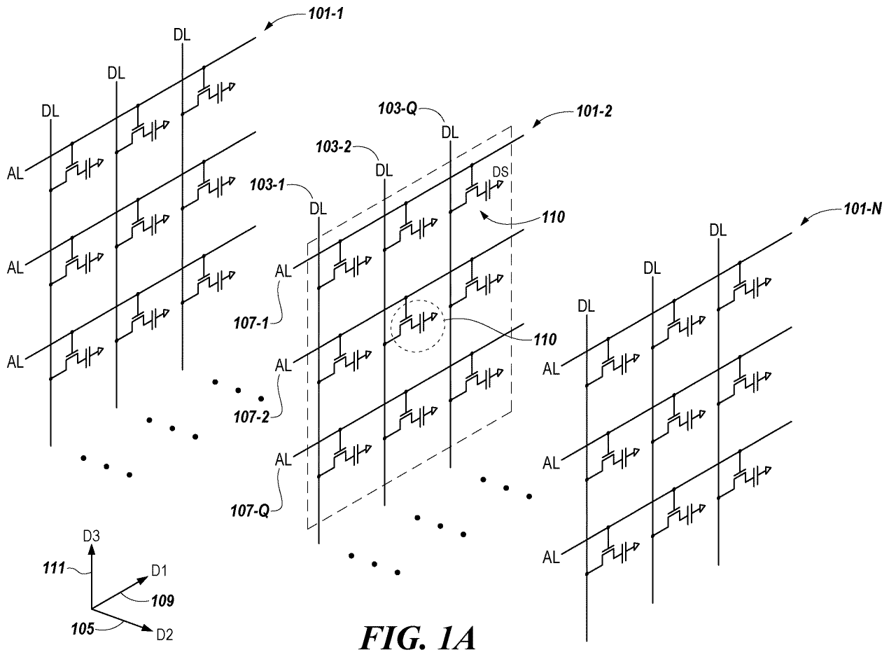

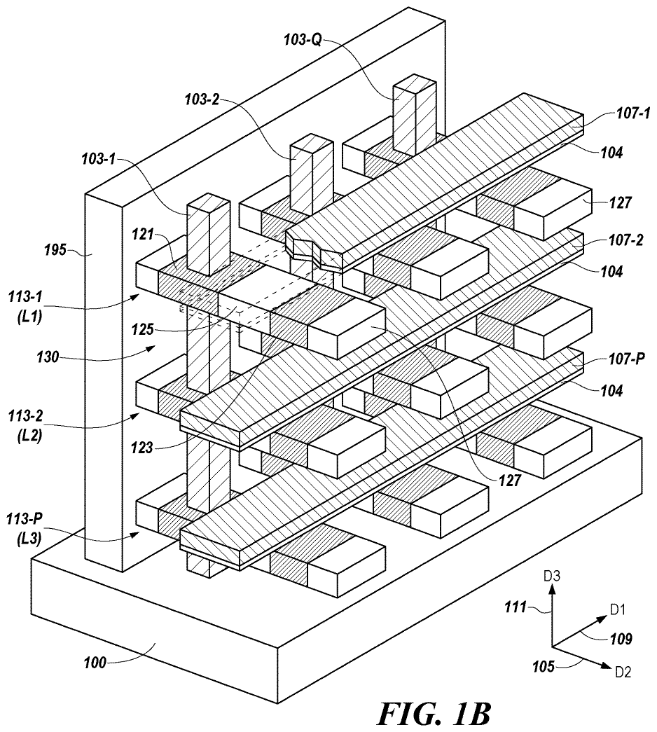

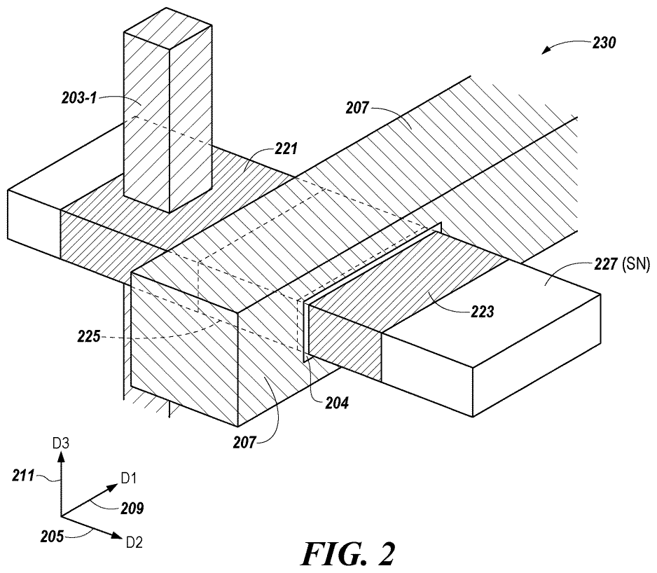

The figures herein follow a numbering convention in which the first digit or digits correspond to the figure number of the drawing and the remaining digits identify an element or component in the drawing. Similar elements or components between different figures may be identified by the use of similar digits. For example, reference numeral 104 may reference element “04” in FIG. 1, and a similar element may be referenced as 204 in FIG. 2. Multiple analogous elements within one figure may be referenced with a reference numeral followed by a hyphen and another numeral or a letter. For example, 302-1 may reference element 302-1 in FIG. 3 and 302-2 may reference element 302-2, which may be analogous to element 302-1. Such analogous elements may be generally referenced without the hyphen and extra numeral or letter. For example, elements 302-1 and 302-2 or other analogous elements may be generally referenced as 302.

FIG. 1A is a schematic illustration of a horizontal access device in a vertical three-dimensional (3D) memory in accordance a number of embodiments of the present disclosure. FIG. 1A illustrates a circuit diagram showing a cell array of a 3D semiconductor memory device according to embodiments of the present disclosure. FIG. 1A illustrates that a cell array may have a plurality of sub cell arrays 101-1, 101-2, . . . , 101-N. The sub cell arrays 101-1, 101-2, . . . , 101-N may be arranged along a second direction (D2) 105. Each of the sub cell arrays, e.g., sub cell array 101-2, may include a plurality of access lines 107-1, 107-2, . . . , 107-Q (which also may be referred to as word lines). Also, each of the sub cell arrays, e.g., sub cell array 101-2, may include a plurality of digit lines 103-1, 103-2, . . . , 103-Q (which also may be referred to as bit lines, data lines, or sense lines). In FIG. 1A, the access lines 107-1, 107-2, . . . , 107-Q are illustrated extending in a first direction (D1) 109 and the digit lines 103-1, 103-2, . . . , 103-Q are illustrated extending in a third direction (D3) 111. According to embodiments, the first direction (D1) 109 and the second direction (D2) 105 may be considered in a horizontal (“X-Y”) plane. The third direction (D3) 111 may be considered in a vertical (“Z”) plane. Hence, according to embodiments described herein, the digit lines 103-1, 103-2, . . . , 103-Q are extending in a vertical direction, e.g., third direction (D3) 111.

A memory cell, e.g., memory cell 110, may include an access device, e.g., access transistor, and a storage node located at an intersection of each access line 107-1, 107-2, . . . , 107-Q and each digit line 103-1, 103-2, . . . , 103-Q. Memory cells may be written to, or read from, using the access lines 107-1, 107-2, . . . , 107-Q and digit lines 103-1, 103-2, . . . , 103-Q. The access lines 107-1, 107-2, . . . , 107-Q may conductively interconnect memory cells along horizontal rows of each sub cell array 101-, 101-2, . . . , 101-N, and the digit lines 103-1, 103-2, . . . , 103-Q may conductively interconnect memory cells along vertical columns of each sub cell array 101-, 101-2, . . . , 101-N. One memory cell, e.g. 110, may be located between one access line, e.g., 107-2, and one digit line, e.g., 103-2. Each memory cell may be uniquely addressed through a combination of an access line 107-1, 107-2, . . . , 107-Q and a digit line 103-1, 103-2, . . . , 103-Q.

The access lines 107-1, 107-2, . . . , 107-Q may be or include conducting patterns (e.g., metal lines) disposed on and spaced apart from a substrate. The access lines 107-1, 107-2, . . . , 107-Q may extend in a first direction (D1) 109. The access lines 107-1, 107-2, . . . , 107-Q in one sub cell array, e.g., 101-2, may be spaced apart from each other in a vertical direction, e.g., in a third direction (D3) 111.

The digit lines 103-1, 103-2, . . . , 103-Q may be or include conductive patterns (e.g., metal lines) extending in a vertical direction with respect to the substrate, e.g., in a third direction (D3) 111. The digit lines in one sub cell array, e.g., 101-2, may be spaced apart from each other in the first direction (D1) 109.

A gate of a memory cell, e.g., memory cell 110, may be connected to an access line, e.g., 107-2, and a first conductive node, e.g., first source/drain region, of an access device, e.g., transistor, of the memory cell 110 may be connected to a digit line, e.g., 103-2. Each of the memory cells, e.g., memory cell 110, may be connected to a storage node, e.g., capacitor. A second conductive node, e.g., second source/drain region, of the access device, e.g., transistor, of the memory cell 110 may be connected to the storage node, e.g., capacitor. While first and second source/drain region references are used herein to denote two separate and distinct source/drain regions, it is not intended that the source/drain region referred to as the “first” and/or “second” source/drain regions have some unique meaning. It is intended only that one of the source/drain regions is connected to a digit line, e.g., 103-2, and the other may be connected to a storage node.

FIG. 1B is a perspective view illustrating a portion of a horizontal access device in vertical three dimensional (3D) memory, e.g., a portion of a sub cell array 101-2 shown in FIG. 1A as a vertically oriented stack of memory cells in an array, in accordance with a number of embodiments of the present disclosure.

As shown in FIG. 1B, a substrate 100 may have formed thereon one of the plurality of sub cell arrays, e.g., 101-2, described in connection with FIG. 1A. For example, the substrate 100 may be or include a silicon substrate, a germanium substrate, or a silicon-germanium substrate, etc. Embodiments, however, are not limited to these examples.

As shown in the example embodiment of FIG. 1B, the substrate 100 may have fabricated thereon a vertically oriented stack of memory cells, e.g., memory cell 110 in FIG. 1A, extending in a vertical direction, e.g., third direction (D3) 111. According to some embodiments the vertically oriented stack of memory cells may be fabricated such that each memory cell, e.g., memory cell 110 in FIG. 1A, is formed on plurality of vertical levels, e.g., a first level (L1), a second level (L2), and a third level (L3). The repeating, vertical levels, L1, L2, and L3, may be arranged, e.g., “stacked”, a vertical direction, e.g., third direction (D3) 111 shown in FIG. 1A, and may be separated from the substrate 100 by an insulator material. Each of the repeating, vertical levels, L1, L2, and L3 may include a plurality of discrete components, e.g., regions, to the horizontally oriented access devices 130, e.g., transistors, and storage nodes, e.g., capacitors, including access line 107-1, 107-2, . . . , 107-Q connections and digit line 103-1, 103-2, . . . , 103-Q connections. The plurality of discrete components to the horizontally oriented access devices 130, e.g., transistors, may be formed in a plurality of iterations of vertically, repeating layers within each level, as described in more detail below, and may extend horizontally in the second direction (D2) 105, analogous to second direction (D2) 105 shown in FIG. 1A.

The plurality of discrete components to the laterally oriented access devices 130, e.g., transistors, may include a first source/drain region 121 and a second source/drain region 123 separated by a channel region 125, extending laterally in the second direction (D2) 105, and formed in a body of the access devices. In some embodiments, the channel region 125 may include silicon, germanium, silicon-germanium, and/or indium gallium zinc oxide (IGZO). In some embodiments, the first and the second source/drain regions, 121 and 123, can include an n-type dopant region formed in a p-type doped body to the access device to form an n-type conductivity transistor. In some embodiments, the first and the second source/drain regions, 121 and 123, may include a p-type dopant formed within an n-type doped body to the access device to form a p-type conductivity transistor. By way of example, and not by way of limitation, the n-type dopant may include phosphorous (P) atoms and the p-type dopant may include atoms of boron (B) formed in an oppositely doped body region of polysilicon semiconductor material. Embodiments, however, are not limited to these examples.

The storage node 127, e.g., capacitor, may be connected to one respective end of the access device. As shown in FIG. 1B, the storage node 127, e.g., capacitor, may be connected to the second source/drain region 123 of the access device. The storage node may be or include memory elements capable of storing data. Each of the storage nodes may be a memory element using one of a capacitor, a magnetic tunnel junction pattern, and/or a variable resistance body which includes a phase change material, etc. Embodiments, however, are not limited to these examples. In some embodiments, the storage node associated with each access device of a unit cell, e.g., memory cell 110 in FIG. 1A, may similarly extend in the second direction (D2) 105, analogous to second direction (D2) 105 shown in FIG. 1A.

As shown in FIG. 1B a plurality of horizontally oriented access lines 107-1, 107-2, . . . , 107-Q extend in the first direction (D1) 109, analogous to the first direction (D1) 109 in FIG. 1A. The plurality of horizontally oriented access lines 107-1, 107-2, . . . , 107-Q may be analogous to the access lines 107-1, 107-2, . . . , 107-Q shown in FIG. 1A. The plurality of horizontally oriented access lines 107-1, 107-2, . . . , 107-Q may be arranged, e.g., “stacked”, along the third direction (D3) 111. The plurality of horizontally oriented access lines 107-1, 107-2, . . . , 107-Q may include a conductive material. For example, the conductive material may include one or more of a doped semiconductor, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc. Embodiments, however, are not limited to these examples.

Among each of the vertical levels, (L1), (L2), and (L3), the horizontally oriented memory cells, e.g., memory cell 110 in FIG. 1A, may be spaced apart from one another horizontally in the first direction (D1) 109. However, the plurality of discrete components to the horizontally oriented access devices 130, e.g., first source/drain region 121 and second source/drain region 123 separated by a channel region 125, extending laterally in the second direction (D2) 105, and the plurality of horizontally oriented access lines 107-1, 107-2, . . . , 107-Q extending laterally in the first direction (D1) 109, may be formed within different vertical layers within each level. For example, the plurality of horizontally oriented access lines 107-1, 107-2, . . . , 107-Q, extending in the first direction (D1) 109, may be formed on a top surface opposing and electrically coupled to the channel regions 125, separated therefrom by a gate dielectric, and orthogonal to horizontally oriented access devices 130, e.g., transistors, extending in laterally in the second direction (D2) 105. In some embodiments, the plurality of horizontally oriented access lines 107-1, 107-2, . . . , 107-Q, extending in the first direction (D1) 109 are formed in a higher vertical layer, farther from the substrate 100, within a level, e.g., within level (L1), than a layer in which the discrete components, e.g., first source/drain region 121 and second source/drain region 123 separated by a channel region 125, of the horizontally oriented access device are formed.

As shown in the example embodiment of FIG. 1B, the digit lines, 103-1, 103-2, . . . , 103-Q, extend in a vertical direction with respect to the substrate 100, e.g., in a third direction (D3) 111. Further, as shown in FIG. 1B, the digit lines, 103-1, 103-2, . . . , 103-Q, in one sub cell array, e.g., sub cell array 101-2 in FIG. 1A, may be spaced apart from each other in the first direction (D1) 109. The digit lines, 103-1, 103-2, . . . , 103-Q, may be provided, extending vertically relative to the substrate 100 in the third direction (D3) 111 in vertical alignment with source/drain regions to serve as first source/drain regions 121 or, as shown, be vertically adjacent first source/drain regions 121 for each of the horizontally oriented access devices 130, e.g., transistors, extending laterally in the second direction (D2) 105, but adjacent to each other on a level, e.g., first level (L1), in the first direction (D1) 109. Each of the digit lines, 103-1, 103-2, . . . , 103-Q, may vertically extend, in the third direction (D3), on sidewalls, adjacent first source/drain regions 121, of respective ones of the plurality of horizontally oriented access devices 130, e.g., transistors, that are vertically stacked. In some embodiments, the plurality of vertically oriented digit lines 103-1, 103-2, . . . , 103-Q, extending in the third direction (D3) 111, may be connected to side surfaces of the first source/drain regions 121 directly and/or through additional contacts including metal silicides.

For example, a first one of the vertically extending digit lines, e.g., 103-1, may be adjacent a sidewall of a first source/drain region 121 to a first one of the horizontally oriented access devices 130, e.g., transistors, in the first level (L1), a sidewall of a first source/drain region 121 of a first one of the horizontally oriented access devices 130, e.g., transistors, in the second level (L2), and a sidewall of a first source/drain region 121 a first one of the horizontally oriented access devices 130, e.g., transistors, in the third level (L3), etc. Similarly, a second one of the vertically extending digit lines, e.g., 103-2, may be adjacent a sidewall to a first source/drain region 121 of a second one of the horizontally oriented access devices 130, e.g., transistors, in the first level (L1), spaced apart from the first one of horizontally oriented access devices 130, e.g., transistors, in the first level (L1) in the first direction (D1) 109. And the second one of the vertically extending digit lines, e.g., 103-2, may be adjacent a sidewall of a first source/drain region 121 of a second one of the laterally oriented access devices 130, e.g., transistors, in the second level (L2), and a sidewall of a first source/drain region 121 of a second one of the horizontally oriented access devices 130, e.g., transistors, in the third level (L3), etc. Embodiments are not limited to a particular number of levels.

The vertically extending digit lines, 103-1, 103-2, . . . , 103-Q, may include a conductive material, such as, for example, one of a doped semiconductor material, a conductive metal nitride, metal, and/or a metal-semiconductor compound. The digit lines, 103-1, 103-2, . . . , 103-Q, may correspond to digit lines (DL) described in connection with FIG. 1A.

As shown in the example embodiment of FIG. 1B, a conductive body contact may be formed extending in the first direction (D1) 109 along an end surface of the horizontally oriented access devices, e.g., transistors, in each level (L1), (L2), and (L3) above the substrate 100. The body contact may be connected to a body e.g., body region, of the horizontally oriented access devices, e.g., transistors, in each memory cell, e.g., memory cell 110 in FIG. 1A. The body contact may include a conductive material such as, for example, one of a doped semiconductor material, a conductive metal nitride, metal, and/or a metal-semiconductor compound.

Although not shown in FIG. 1B, an insulating material may fill other spaces in the vertically stacked array of memory cells. For example, the insulating material may include one or more of a silicon oxide material, a silicon nitride material, and/or a silicon oxynitride material, etc. Embodiments, however, are not limited to these examples.

FIG. 2 illustrates a portion of a horizontal access device in vertical three-dimensional (3D) memory in accordance with a number of embodiments of the present disclosure. FIG. 2 illustrates in more detail a unit cell, e.g., memory cell 110 in FIG. 1, of the vertically stacked array of memory cells, e.g., within a sub cell array 101-2 in FIG. 1, according to some embodiments of the present disclosure. As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region of the horizontally oriented access devices 230, e.g., transistors. The first and the second source/drain regions, 221 and 223, may be formed from an n-type or p-type dopant doped in the body region. However, embodiments are not so limited.

For example, for an n-type conductivity transistor construction the body region of the laterally oriented access devices 230, e.g., transistors, may be formed of a low doped p-type (p-) semiconductor material. In one embodiment, the body region and the channel region 225 separating the first and the second source/drain regions, 221 and 223, may include a low doped, p-type (e.g., low dopant concentration (p-)) polysilicon (Si) material consisting of boron (B) atoms as an impurity dopant to the polycrystalline silicon. The first and the second source/drain regions, 221 and 223, may also comprise a metal, and/or metal composite materials containing ruthenium (Ru), molybdenum (Mo), nickel (Ni), titanium (Ti), copper (Cu), a highly doped degenerate semiconductor material, and/or at least one of indium oxide (In2O3), or indium tin oxide (In2-xSnxO3), formed using an atomic layer deposition process, etc. Embodiments, however, are not limited to these examples. As used herein, a degenerate semiconductor material is intended to mean a semiconductor material, such as polysilicon, containing a high level of doping with significant interaction between dopants, e.g., phosphorus (P), boron (B), etc. Non-degenerate semiconductors, by contrast, contain moderate levels of doping, where the dopant atoms are well separated from each other in the semiconductor host lattice with negligible interaction.

In this example, the first and the second source/drain regions, 221 and 223, may include a high dopant concentration, n-type conductivity impurity (e.g., high dopant (n+)) doped in the first and the second source/drain regions, 221 and 223. In some embodiments, the high dopant, n-type conductivity first and second drain regions 221 and 223 may include a high concentration of phosphorus (P) atoms deposited therein. Embodiments, however, are not limited to this example. In other embodiments, the horizontally oriented access devices 230, e.g., transistors, may be of a p-type conductivity construction in which case the impurity, e.g., dopant, conductivity types would be reversed.

As shown in FIG. 2, the first and the second source/drain regions, 221 and 223, may be impurity doped regions to the laterally oriented access devices 230, e.g., transistors. The first and the second source/drain regions may be separated by a channel region 225 formed in a body of semiconductor material, e.g., body region, of the horizontally oriented access devices 230, e.g., transistors. The first and the second source/drain regions, 221 and 223, may be formed from an n-type or p-type dopant doped in the body region. However, embodiments are not so limited.

The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 221 and is in electrical contact with the body contact. Further, as shown in the example embodiment of FIG. 2, an access line, e.g., 207, analogous to the access lines 107-1, 107-2, . . . , 107-Q shown in FIG. 1, may disposed on a top surface opposing and coupled to a channel region 225, separated therefrom by a gate dielectric 204. The gate dielectric 204 may be, for example, a high-k dielectric material, a silicon oxide material, a silicon nitride material, a silicon oxynitride material, etc., or a combination thereof. Embodiments are not so limited. For example, in high-k dielectric material examples the gate dielectric material 304 may include one or more of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobite, etc.

As shown in the example embodiment of FIG. 2, a digit line, e.g., 203-1, analogous to the digit lines 103-1, 103-2, . . . , 103-Q in FIG. 1, may be vertically extending in the third direction (D3) 211 adjacent a sidewall of the first source/drain region 221 in the body to the horizontally oriented access devices 230, e.g., transistors horizontally conducting between the first and the second source/drain regions 221 and 223 along the second direction (D2) 205. In this embodiment, the vertically oriented digit line 203-1 is formed symmetrically, in vertical alignment, in electrical contact with the first source/drain region 221. The digit line 203-1 may be formed in contact with an insulator material such that there is no body contact within channel region 225.

As shown in the example embodiment of FIG. 2, the digit line 203-1 may be formed symmetrically within the first source/drain region 221 such that the first source/drain region 221 surrounds the digit line 203-1 all around. The first source/drain region 221 may occupy an upper portion in the body of the laterally oriented access devices 230, e.g., transistors. For example, the first source/drain region 221 may have a bottom surface within the body of the horizontally oriented access device 230 which is located higher, vertically in the third direction (D3) 211, than a bottom surface of the body of the laterally, horizontally oriented access device 230. As such, the laterally, horizontally oriented access device 230 may have a body portion which is below the first source/drain region 321 and is in contact with the body contact. An insulator material may fill the body contact such that the first source/drain region 221 may not be in electrical contact with channel region 225. Further, as shown in the example embodiment of FIG. 2, an access line, e.g., 207, analogous to the access lines 107-1, 107-2, . . . , 107-Q shown in FIG. 1, may be disposed all around and coupled to a channel region 225, separated therefrom by a gate dielectric 204.

Although the digit line 203-1 is described above as being formed symmetrically within the first source/drain region 221 such that the first source/drain region 221 surrounds the digit line 203-1 all around, embodiments are not so limited. For instance, in some examples, the digit line 203-1 can be formed asymmetrically. In this embodiment, the vertically oriented digit line is formed asymmetrically adjacent in electrical contact with the first source/drain regions 221. The digit line may be formed asymmetrically to reserve room for a body contact in the channel region 225.

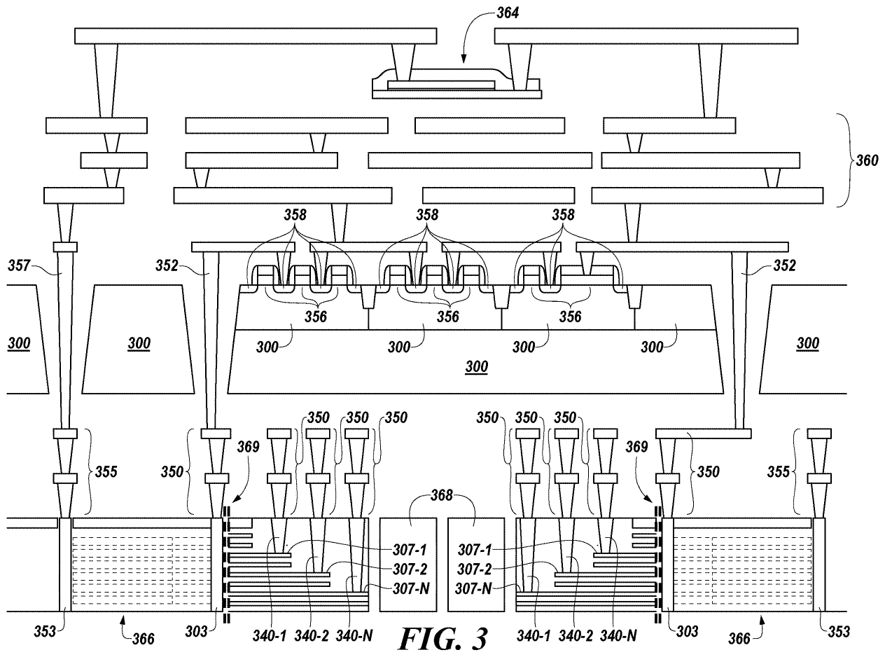

FIG. 3 is a schematic illustration of a vertical three dimensional (3D) memory in functional association with logic components for the 3D memory array. The logic components may include complementary metal oxide semiconductor (CMOS) components such as input/output (I/O) connections, sense amplifiers (SAs), digit line multiplexers (DLMUXs), sub-wordline drivers (SWDs), etc., in accordance with a number of embodiments of the present disclosure. FIG. 3A includes horizontally oriented access lines 307-1, 307-2, . . . , 307-N (individually or collectively referred to as horizontally access lines 307), access line contacts 340-1, 340-2, . . . , 340-N (individually or collectively referred to as access line contacts 340), and vertically oriented sense lines 303 (e.g., digit lines), connected to a dynamic random access memory (DRAM) array of horizontally oriented, vertically stacked memory cells, having horizontally oriented access devices and horizontally oriented storage nodes.

The schematic illustration in FIG. 3 portrays different components relating to the function, operation, and control of the vertical 3D memory at different vertical heights on the page of the drawing sheet. In the portion of the vertical 3D memory at the lowest vertical height shown in FIG. 3 is illustrated a dynamic random access memory array (DRAM) of horizontally oriented, vertically stacked memory cells in a plurality of levels. The outermost edges of the bottom of the drawing sheet illustrate the 3D DRAM in an “x”-direction, cross-sectional view along a “length” of horizontally oriented access devices connected to horizontally oriented storage nodes. In the center region of the bottom of the drawing sheet, partitioned by a cut line, is illustrated an example embodiment of a staircase structure in a periphery of the vertical 3D memory, along a y-direction, cross sectional view (end on to the memory cells) that includes horizontally oriented access lines 307—which would be running into and out of the plane of the drawing sheet in the outermost x-direction view of the 3D DRAM memory array. As used herein, the term “periphery of the vertical 3D memory” refers to an area located outside of the array of memory cells for forming and making electrical contacts to array of memory cells. In some embodiments, periphery components and electrical connections can consume more area and have greater die space usage than that of the array of memory cells itself. Isolation regions 368 may separate neighboring arrays of vertical 3D memory in “x” and/or “y” directions of a memory die on a memory wafer.

To connect “on pitch” in a wafer to wafer architecture, e.g., logic wafer to memory wafer, various electrical connection routing challenges may exist. As used herein, the term “pitch” is intended to refer to a length and/or width dimension of a conductive feature and its minimum separation from a next feature according to a certain design rule or fabrication capability. Thus “on-pitch” as used herein is intended to mean a capability to establish and match electrical features, circuitry, and/or components to one another between different wafers, e.g., logic wafer connections to memory wafer connections. Hence, in the schematic illustration of FIG. 3A, forming electrical connections to circuitry and components of different size and locations elsewhere in the schematic illustration, while accommodating design rules, including power consumption, die density usage, and overlay alignment constraints, present hurdles. Larger than memory cell access device transistor size, the transistor component size for address decode logic, sense amplifiers circuitry, DLMUXs, and SWDs, may all consume more space and be located elsewhere as logic, e.g., CMOS logic, shown above in the schematic of FIG. 3A, but have electrical connection to the 3D DRAM array. For example, in the schematic illustration of FIG. 3, access line contacts 340 are coupled to the access lines 307. In some embodiments, the access line contacts 340 can be coupled to additional transistor logic in the form of SWDs 350. In some embodiments, SWDs 350 can be coupled to a power source that can supply power to the access lines 307 through the access line contacts 340. The transistor size to the access devices in the memory cell portion 366 of the vertical 3D memory may have a significantly smaller “pitch,” as described elsewhere herein.

As further shown in the schematic illustration of FIG. 3 a portion of the logic controlling the function and operation of the vertical 3D memory array 366 can be in logic shown further above in the drawing sheet. This portion of CMOS logic 356, e.g., circuitry, can include address decode circuity, DLMUXs, and/or sense amplifier (SA) transistor logic, etc. Larger and appropriately doped source/drain region 358 sizes (e.g., larger and more heavier doping than memory cell access device size and doping concentrations) and may be formed separately on logic wafer substrate materials 300. As described herein, a contact 369 can couple the top surfaces of digit lines 303 to conductive lines and/or logic 352 and 351. Accordingly, conductive lines and/or logic 352 and 351 can couple CMOS circuitry 356 to digit lines 303 associated with the array 366, as well as to conductive lines 360 for I/O connections. Further, power supply transistor logic 364 may control one or more storage node electrodes 353, e.g., top electrode/common nodes, for the storage nodes in the array portion 366 via conductive lines and/or logic 357 and 355 pathways. Embodiments are not limited to this schematic example shown in FIG. 3.

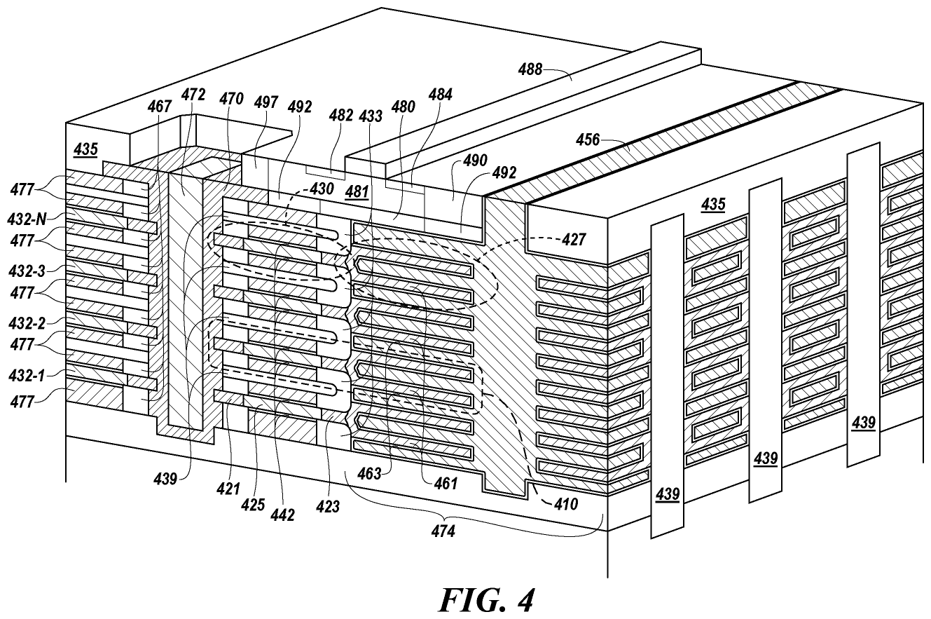

FIG. 4 illustrates a portion of a vertical three-dimensional (3D) memory with a multiplexer in accordance with a number of embodiments of the present disclosure. FIG. 4 is a perspective view of a three-dimensional (3D) dynamic random access memory (DRAM) array 400 having horizontally oriented memory cells 410, vertically stacked in a plurality of levels, e.g., L1, L2, and L3 in FIG. 1B. The example embodiment of FIG. 4 is illustrating an array of 3D DRAM 400 having horizontally oriented memory cells 410 combinable with multi-wafer logic in accordance with a number of embodiments of the present disclosure. The horizontally oriented memory cells 410 in the array 400 comprise horizontally oriented access devices 430 at each level, e.g., L1, L2, and L3 in FIG. 1B, having first source/drain regions 421 and second source/drain regions 423 separated by channel regions 425. Horizontally oriented access lines 477 form gates separated from the channel regions 425 by gate dielectric material 442. As shown in the example embodiment, horizontally oriented storage nodes 474, at each level L1, L2, and L3 in FIG. 1B, are electrically coupled to the second source/drain regions 473 of the horizontally oriented access devices 430. The horizontally oriented storage nodes 474 include a first electrode 461, e.g., bottom electrode, and a second electrode 456, e.g., top electrode and/or common node, separated by a dielectric material 461. In some embodiments, the horizontally oriented storage nodes 474 are multi-sided storage nodes, e.g., double sided-capacitors, as shown in FIG. 4. Vertically oriented digit lines 470/472 are electrically connected to the first source/drain regions 421 of the horizontally oriented access devices 430. In some embodiments, a portion 470 of the vertically oriented digit lines are epitaxially formed (e.g., grown), vertically oriented digit lines 470.

A multiplexer device can be formed on the 3D DRAM array 400 in a multiplexer silicon layer 435. The multiplexer device can include first source/drain region 482 and second source/drain region 484. A channel region for the multiplexer can be between the first source/drain region 482 and a second source/drain region 484 and the multiplexer device can include body region 481. A multiplexer word line 488 can be formed over the channel region of the multiplexer device. The multiplexer word line 488 can be biased to turn the multiplexer device on and off.

The multiplexer device can include a conductive contact 480 (e.g., body contact region) that contacts the body region 481. Conductive contact 480 can be coupled to a voltage source to provide a voltage potential to bias the multiplexer device and reduce and/or eliminate floating body effects (FBE). The conductive contact 480 can be coupled to a voltage source to provide a voltage potential to bias the multiplexer device and control the threshold voltage for activating and/or deactivating the multiplexer device. The conductive contact 480 can be coupled to a voltage source to provide a voltage potential to bias the multiplexer device and reduce and/or eliminate plate disturb from the upper electrode of the storage nodes in the array of memory cells. The conductive contact 480 can separate the body region 481 from the vertical stack, including an access device region and a storage node region. The conductive contact 480 can be separated from electrode 456 and from the digit line 470 by dielectric material 492.

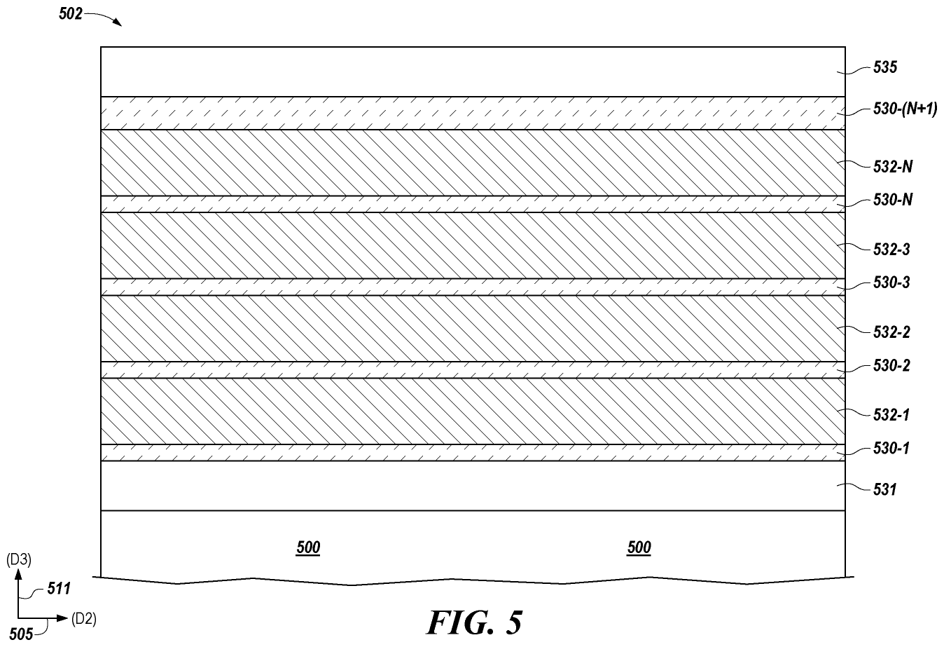

FIG. 5 is a cross-sectional view, at one stage of a semiconductor fabrication process, for vertical three-dimensional (3D) memory with a multiplexer, in accordance with a number of embodiments of the present disclosure.

In the example embodiment shown in the example of FIG. 5, the method comprises forming alternating layers of a silicon germanium (SiGe) material, 430-1, 430-2, . . . , 430-N (collectively referred to as silicon germanium (SiGe) 530), and a silicon (Si) material, 532-1, 532-2, . . . , 532-N (collectively referred to as epitaxially grown, single crystalline silicon (Si) material 532), in repeating iterations to form a vertical stack 502 on a working surface of a semiconductor substrate 500. In one embodiment, the silicon germanium (SiGe) 530 can be deposited on a dielectric 531 to have a thickness, e.g., vertical height in the third direction (D3), in a range of five (5) nm to thirty (30) nm. In one embodiment, the silicon 532 can be deposited to have a thickness (t2), e.g., vertical height, in a range of thirty (30) nanometers (nm) to sixty (60) nm. Embodiments, however, are not limited to these examples. As shown in FIG. 5, a vertical direction 511 is illustrated as a third direction (D3), e.g., z-direction in an x-y-z coordinate system, analogous to the third direction (D3), among first, second, and third directions, shown in FIGS. 1-2.

In some embodiments, the silicon germanium (SiGe), 530-1, 530-2, . . . , 530-N, may be a mix of silicon and germanium. By way of example, and not by way of limitation, the silicon germanium (SiGe) 530 may be grown on a dielectric 531 by way of epitaxial growth. Embodiments are not limited to these examples. In some embodiments, the single crystalline silicon (Si) material, 532-1, 532-2, . . . , 532-N, may comprise a silicon (Si) material in a polycrystalline and/or amorphous state. The single crystalline silicon (Si) material, 532-1, 532-2, . . . , 532-N, may be a low doped, p-type (p-) epitaxially grown, single crystalline silicon (Si) material. The silicon material, 532-1, 532-2, . . . , 532-N, may also be formed by epitaxially growth on the silicon germanium (SiGe) 530. After the epitaxially grown silicon germanium (SiGe) 530 has been formed, the seed is turned to pure silicon. Embodiments, however, are not limited to these examples.

The repeating iterations of alternating silicon germanium (SiGe), 530-1, 530-2, . . . , 530-N layers and epitaxially grown, single crystalline silicon (Si) material, 532-1, 532-2, . . . , 532-N layers may be deposited according to a semiconductor fabrication process such as chemical vapor deposition (CVD) in a semiconductor fabrication apparatus. Embodiments, however, are not limited to this example and other suitable semiconductor fabrication techniques may be used to deposit the alternating layers of epitaxially grown silicon germanium (SiGe) and epitaxially grown, single crystalline silicon (Si) material, in repeating iterations to form the vertical stack 502.

The layers may occur in repeating iterations vertically. In the example of FIG. 5, N+1 tiers, numbered 1, 2, 3, N, and N+1 of the repeating iterations are shown. For example, the stack may include: a first silicon germanium (SiGe) 530-1, a first Si material 532-1, a second SiGe material 530-2, a second Si material 532-2, a third SiGe material 530-3, and a Si material 532-3, in further repeating iterations. Embodiments, however, are not limited to this example and more or fewer repeating iterations may be included.

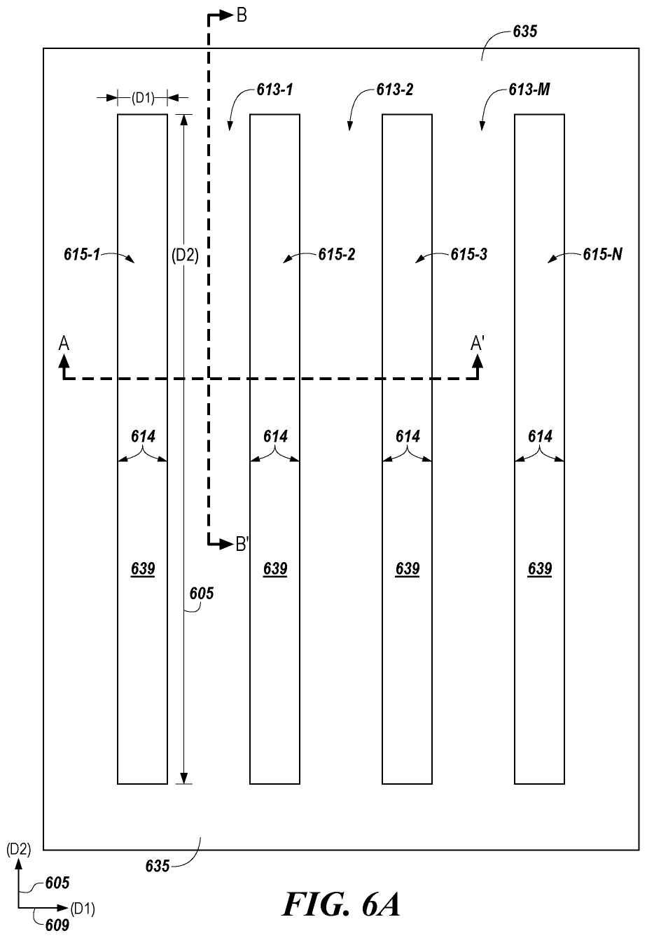

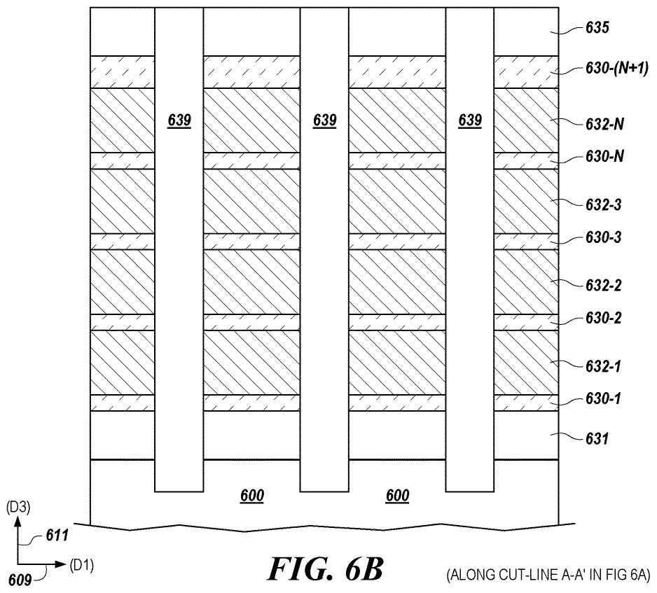

FIG. 6A to 6B illustrate an example method, at one stage of a semiconductor fabrication process, for vertical three-dimensional (3D) memory with a multiplexer, in accordance with a number of embodiments of the present disclosure.

FIG. 6A illustrates a top-down view of a semiconductor structure, at a particular point in time, in a semiconductor fabrication process, according to one or more embodiments. In the example embodiment shown in the example of FIG. 6A, the method comprises using an etchant process to form a plurality of vertical openings 615 (e.g., a plurality of second vertical openings), having a first horizontal direction (D1) 609 and a second horizontal direction (D2) 605, through the vertical stack to the substrate. In one example, as shown in FIG. 6A, the plurality of vertical openings 615 are extending predominantly in the second horizontal direction (D2) 605 and may form elongated vertical, pillar columns 613-1, 613-2, . . . , 613-M (collectively and/or independently referred to as 613), with sidewalls 614 in the vertical stack. The plurality of first vertical openings 600 may be formed using photolithographic techniques to pattern a photolithographic mask 635, e.g., to form a hard mask (HM), on the vertical stack prior to etching the plurality of first vertical openings 615. Similar semiconductor process techniques may be used at other points of the semiconductor fabrication process described herein.

FIG. 6B is a cross sectional view, taken along cut-line A-A′ in FIG. 6A, showing another view of the semiconductor structure at a particular time in the semiconductor fabrication process. The cross-sectional view shown in FIG. 6B shows the repeating iterations of alternating layers of silicon germanium (SiGe) 630 and silicon (Si) material 632 on a semiconductor substrate 600 to form the vertical stack, e.g. 402 as shown in FIG. 4.

As shown in FIG. 6B, a plurality of vertical openings may be formed through the layers within the vertically stacked memory cells to expose vertical sidewalls in the vertical stack and form elongated vertical pillar columns 613 and then filled with a first dielectric material 639. The vertical openings may be formed through the repeating iterations of the silicon germanium (SiGe) 630 and the silicon (Si) material 632.

The vertical openings may be formed to expose vertical sidewalls in the vertical stack. The vertical openings may extend in a second horizontal direction (D2) 605 to form the elongated vertical, pillar columns with first vertical sidewalls in the vertical stack and then filled with the dielectric material 639.

As shown in FIG. 6B, a first dielectric material 639, such as an oxide or other suitable spin on dielectric (SOD), may be deposited in the vertical openings, using a process such as CVD, to fill the vertical openings. First dielectric material 639 may also be formed from a silicon nitride (Si3N4) material. In another example, the first dielectric material 639 may include silicon oxy-nitride (SiOxNy), and/or combinations thereof. Embodiments are not limited to these examples. The plurality of first vertical openings may be formed using photolithographic techniques to pattern a photolithographic mask 635, e.g., to form a hard mask (HM), on the vertical stack prior to etching the plurality of first vertical openings. In one embodiment, hard mask 635 may be deposited over silicon germanium (SiGe) 630. Similar semiconductor process techniques may be used at other points of the semiconductor fabrication process described herein.

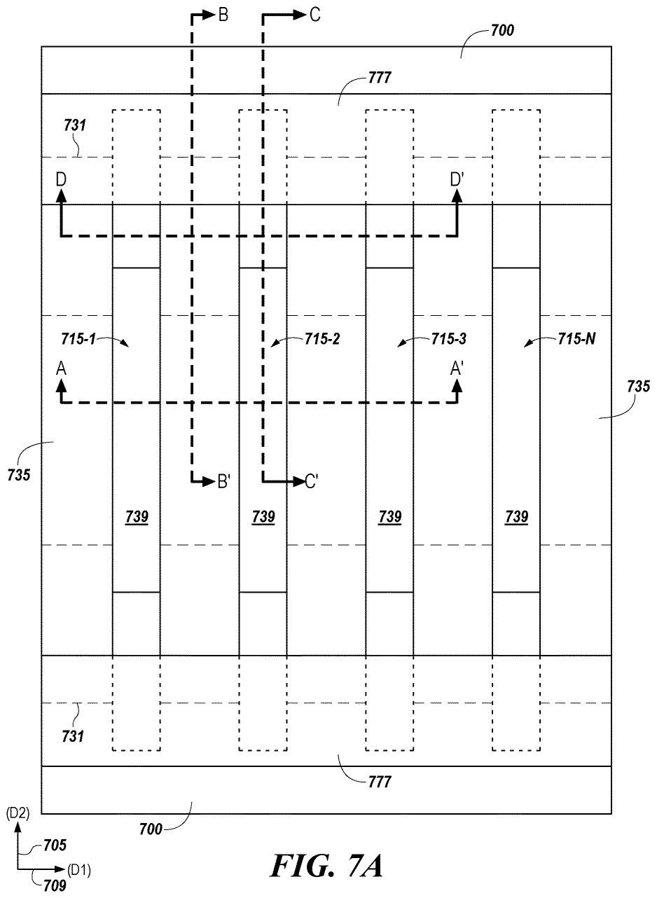

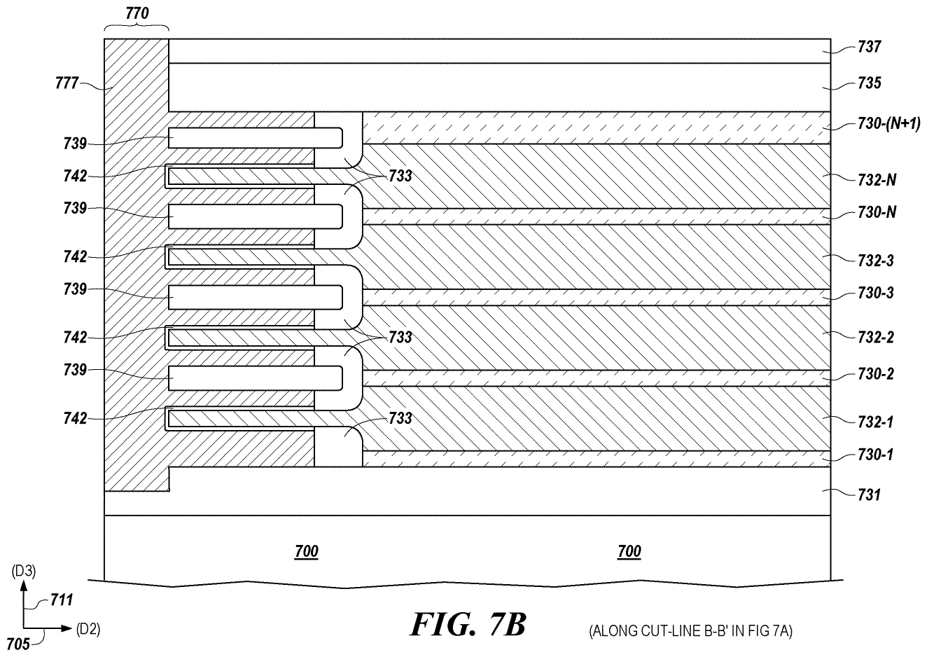

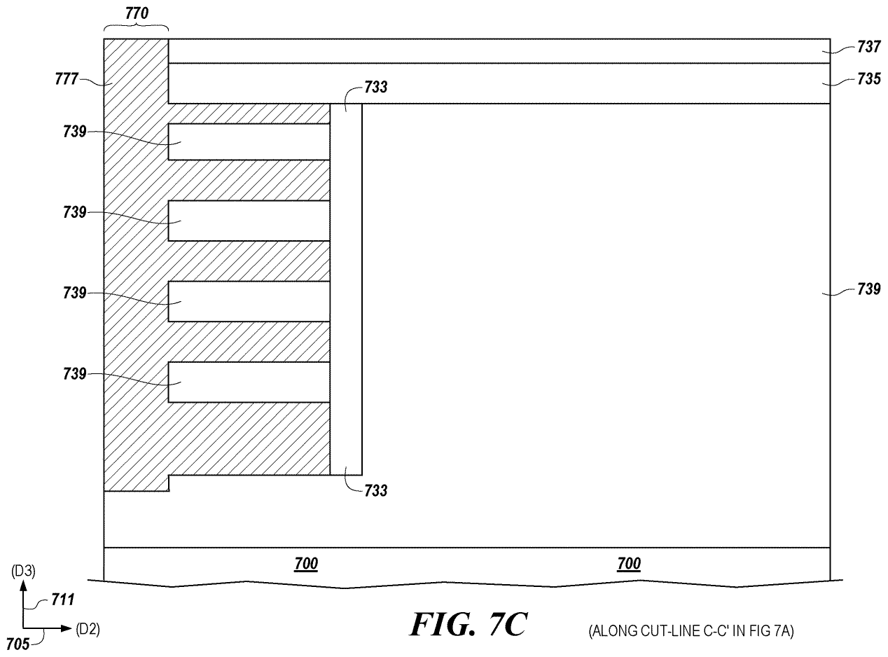

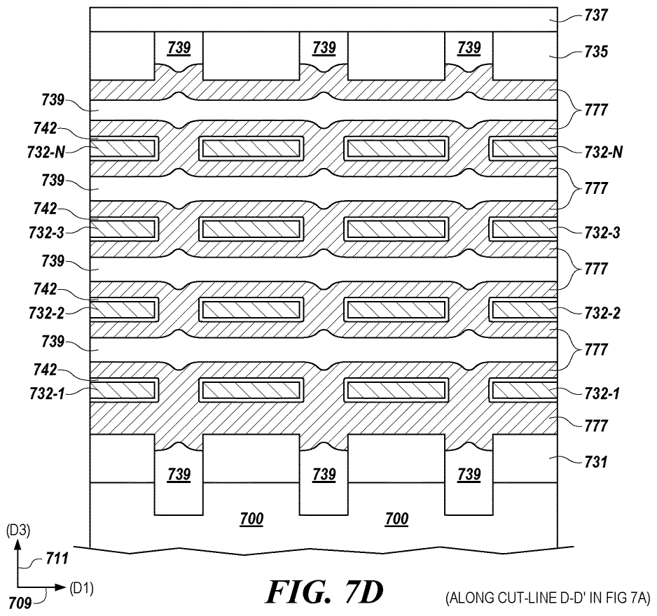

FIGS. 7A to 7D illustrate an example method, at another stage of a semiconductor fabrication process, for vertical three-dimensional (3D) memory with a multiplexer, in accordance with a number of embodiments of the present disclosure. FIG. 7A illustrates a top-down view of a semiconductor structure, at a particular point in time, in a semiconductor fabrication process, according to one or more embodiments.

In the example embodiment of FIG. 7A, the method comprises using a photolithographic process to pattern a photolithographic mask 735. A first conductive material 777 may be deposited above the vertical openings 731. The first conductive material 777 may be deposited in continuous second horizontal openings to form horizontally oriented access lines opposing channel regions of the silicon (Si) material 732. Such a process is further described herein.

For example, the semiconductor fabrication process can include using an etchant process to form a plurality of spaced, vertical openings 731 through the vertical stack by patterning and selectively removing the first dielectric material 739 in the plurality of vertical openings 715 to expose second vertical sidewalls adjacent a first region of the silicon germanium (SiGe). Multiple vertical openings 731 may be formed through the layers of materials. In one example, as shown in FIG. 7A, the spaced, vertical openings 731 are extending predominantly in the first horizontal direction (D2) 709 and may form short vertical squares in the plurality of vertical openings 715 adjacent the vertical stack. The vertical openings 731 may be formed using photolithographic techniques to pattern first dielectric material 739 to form an opening within the vertical stack prior to etching the plurality of vertical openings 715.

The semiconductor fabrication process can further include doping a first source/drain region of the Si material 732. That is, the first Si material 732-1, the second Si material 732-2, the third Si material 732-3, and in further repeating iterations, can be doped. For example, a source/drain region may be formed by gas phase doping a dopant into a side surface portion of the Si material 732. In some embodiments, the source/drain region may be a first source/drain region that will connect to a digit line connection. In one example, gas phase doping may be used to achieve a highly isotropic (e.g., non-directional doping), to form the first source/drain regions for the horizontally oriented access devices. In another example, thermal annealing with doping gas, such as phosphorous (P) may be used with a high energy plasma assist to break the bonding. Embodiments, however, are not so limited and other suitable semiconductor fabrication techniques may be utilized.

The openings 715 may be filled with a dielectric material 739. In one example, a spin on dielectric process may be used to fill the openings 715. In one embodiment, the dielectric material 739 may be an oxide material. However, embodiments are not so limited.

FIG. 7B illustrates a cross sectional view, taken along cut-line A-A′ in FIG. 7A, showing another view of the semiconductor structure at this particular point in one example semiconductor fabrication process of an embodiment of the present disclosure. The cross-sectional view shown in FIG. 7B shows the repeating iterations of alternating layers of the silicon germanium (SiGe) 730 and the silicon (Si) material 732, on a semiconductor substrate 700.

As mentioned in FIG. 7A, the semiconductor fabrication process can include forming vertical openings 715 (e.g., illustrated in FIG. 7A) through the layers within the vertically stacked memory cells to expose vertical sidewalls in the vertical stack 402 as shown in FIG. 4. The vertical openings 715 can extend predominantly in a first horizontal direction. The dielectric material 739, such as an oxide or other suitable spin on dielectric (SOD), may be deposited in the first vertical openings, using a process such as CVD, to fill the first vertical openings. A photolithographic mask 735, e.g., hard mask, may be deposited over the vertical stack using CVD and planarized using chemical mechanical planarization (CMP). Similar semiconductor process techniques may be used at other points of the semiconductor fabrication process described herein.

The semiconductor fabrication process can further include selectively etching the silicon germanium (SiGe) 730 isotropically to form a plurality of first horizontal openings in the first region separating layers of the Si material 732. An etchant may be flowed into the second vertical opening 731 to selectively etch a portion of the epitaxially grown silicon germanium (SiGe) 730 within the stack. As such, the etchant may target the first silicon germanium (SiGe) 730-1, the second silicon germanium (SiGe) 730-2, and the third silicon germanium (SiGe) 730-3 within the stack. The selective etchant process may etch the silicon germanium (SiGe) 730 to form the plurality of first horizontal openings 773. As a result of the etchant process, the vertical thickness (e.g., D3) of the layers of the Si material 732 occurs.

The selective etchant process may comprise a selective etch chemistry of phosphoric acid (H3PO4) or hydrogen fluoride (HF) and/or dissolving the silicon germanium (SiGe) 730 using a selective solvent, among other possible etch chemistries or solvents. Alternatively, or in addition, a selective etch to remove the silicon germanium (SiGe) 730 may consist of one or more etch chemistries selected from an aqueous etch chemistry, a semi-aqueous etch chemistry, a vapor etch chemistry, or a plasma etch chemistries, among other possible selective etch chemistries. For example, a dry etch chemistry of oxygen (O2) or O2 and sulfur dioxide (SO2) may be utilized. As another example, a dry etch chemistries of O2 or of O2 and nitrogen (N2) may be used to selectively etch the silicon germanium (SiGe) 730.

The silicon germanium (SiGe) 730 has now been selectively etched isotropically to form a plurality of first horizontal openings 773 in the first region separating layers of the Si material 732. A second dielectric material 733 may be conformally deposited all around first horizontal opening 773. The second dielectric material 733 may be deposited fully around exposed surfaces in the plurality of first horizontal openings 773. The second dielectric material 733 may serve as a liner around the plurality of first horizonal openings 773. The second dielectric material 733 may be flowed into the vertical opening 731 to cover exposed surfaces of the silicon (Si) material where the silicon germanium (SiGe) was removed to form the plurality of first horizontal openings 773 within the stack.

In one embodiment, the second dielectric material 733 may comprise a nitride material. In another embodiment, second dielectric material 733 may comprise a silicon nitride (Si3N4) material (also referred to herein as “SiN”). In another embodiment the second dielectric material 733 may include silicon dioxide (SiO2) material. In another embodiment the second dielectric material 733 may comprise a silicon oxy-carbide (SiOxCy) material, and/or combinations thereof. Embodiments are not limited to these examples.

In one embodiment, the second dielectric material 733 may be conformally deposited all around exposed surfaces in the plurality of first horizontal openings 773 to have a thickness (t1) of approximately 100 to 300 angstroms (Å). Embodiments, however, are not limited to these examples.

The semiconductor fabrication process can further include depositing the first dielectric material 739 to full the plurality of first horizontal openings 773. For example, a first dielectric material 739, such as an oxide or other suitable spin on dielectric (SOD), is deposited into the plurality of first horizontal openings 773, on the exposed surfaces of the second dielectric material 733, to fill the first horizontal opening 773. The first dielectric material 739 may entirely fill the plurality of first horizontal openings 773. The first dielectric material 739 may be flowed into the vertical openings 731 to fill the vertical openings 731 and to fill the plurality of first horizontal openings 773 within the stack. As such, the first dielectric material 739 may fill the first horizontal openings 773 within the first silicon germanium (SiGe) 730-1, the second silicon germanium (SiGe) 730-2, and the third silicon germanium (SiGe) 730-3 within the stack.

The semiconductor fabrication process can further include selectively etching the second dielectric material 733 from the plurality of first horizontal openings a second length (L2) from the vertical openings 770. An etchant may be flowed into the vertical opening 731 to selectively etch a portion of the second dielectric material 730 within the stack. As such, the etchant may target the second dielectric material 730 within the stack. The selective etchant process may etch the second dielectric material 730 the second length L2. Any selective etch chemistry described herein or otherwise may be utilized for such a selective etchant process.

The semiconductor fabrication process can further include forming a gate dielectric material on exposed surfaces of the reduced vertical thickness of the Si material 732. For example, a gate dielectric material 742 may be formed on exposed surfaces of the Si material 732 to form horizontal access devices. In some embodiments the gate dielectric material may be an oxide material 742. The gate dielectric material 742 may be conformally deposited fully around every surface of the Si material 732 to form gate all around (GAA) gate structures, at the channels of the access device regions. The gates opposing the channel regions provide a subthreshold voltage (sub-Vt) slope in a range of approximately 45 to 100 millivolts per decade (mV/dec).

The gate dielectric material 742 may be deposited on exposed surfaces of the Si material 732 using an atomic layer deposition. In some embodiments the gate dielectric material may be an oxide material. For example, an oxide material may be deposited over the exposed surfaces of the epitaxially grown, single crystalline silicon (Si) material 732 to prevent oxidization of the Si material 732. The oxide material deposition may prevent shorts by protecting the Si material 732 from interactions with the first dielectric material 739. The oxide material may be selectively deposited on exposed surfaces of the Si material 732 using atomic layer deposition. A thermal oxidation process may be used to densify the ALD deposited oxide material. The thermal oxidation process involves forming oxide material from a hybrid oxide material. The hybrid oxide material may combine a low temperature oxide material and a high temperature oxide material.

In the semiconductor fabrication process, a first conductive material 777 may be deposited on the gate dielectric material 742. The first conductive material 777 may be deposited around the Si material 732 such that the first conductive material 777 may have a top portion above the Si material 732 and a bottom portion below the Si material 732 to form gate all around (GAA) gate structures, at the channels of the access device regions. The first conductive material 777 may be conformally deposited into vertical openings 770 and fill the continuous second horizontal openings 743 up to the unetched portions of the oxide material 742, the first dielectric material 739, and the second dielectric material 733. The first conductive material 777 may be conformally deposited using a chemical vapor deposition (CVD) process, plasma enhanced CVD (PECVD), atomic layer deposition (ALD), or other suitable deposition process.

In some embodiments, the first conductive material 777 may comprise one or more of a doped semiconductor (e.g., doped silicon, doped germanium, etc., a conductive metal nitride, e.g., titanium nitride, tantalum nitride, etc.), a metal (e.g., tungsten (W), titanium (Ti), tantalum (Ta), ruthenium (Ru), cobalt (Co), molybdenum (Mo), etc.), and/or a metal-semiconductor compound (e.g., tungsten silicide, cobalt silicide, titanium silicide, etc.), and/or some other combination thereof. The first conductive material 777 entwined with the gate dielectric material may form horizontally oriented access lines opposing a channel region of the epitaxially grown, single crystalline silicon (Si) material (which also may be referred to a word lines).

The first conductive material 777 can be recessed to the channel regions. For example, the first conductive material 777, formed on the gate dielectric material 742, may be recessed and etched away from the third vertical opening 770. In some embodiments, the first conductive material 777 may be etched using an atomic layer etching (ALE) process. In some embodiments, the first conductive material 777 may be etched using an isotropic etch process. The first conductive material 777 may be selectively etched leaving the oxide material 742 covering the Si material 732 and the first dielectric material 739 intact. The first conductive material 777 may be selectively etched in the second direction, in the continuous second horizontal openings, a third distance (DIST 3) in a range of twenty (20) to fifty (50) nanometers (nm) back from the third vertical opening 770. The first conductive material 777 may be selectively etched around the Si material 732 back into the continuous second horizontal openings extending in the first horizontal direction.

FIG. 7C illustrates a cross sectional view, taken along cut-line C-C′ in FIG. 7A, showing another view of the semiconductor structure at this particular point in one example semiconductor fabrication process of an embodiment of the present disclosure. The cross-sectional view shown in FIG. 7C is illustrated extending in the second horizontal direction (D2) 705, left and right in the plane of the drawing sheet, along an axis of the repeating iterations of alternating layers of continuous second horizontal openings 743 and Si material 732.

In FIG. 7C, first dielectric material 739 is shown spaced along a second horizontal direction (D2) 705, extending into and out from the plane of the drawings sheet, for a three-dimensional array of vertically oriented memory cells. At the left end of the drawing sheet is shown the repeating iterations of alternating layers of the first dielectric material 739. The first conductive material 777 may be conformally deposited into third vertical openings 770. The first conductive material 777 is formed on the gate dielectric material. At the right hand of the drawing sheet, the first dielectric material 739 may be seen, separating access device and storage node regions in the first direction (D1).

FIG. 7D illustrates a cross sectional view, taken along cut-line D-D′ in FIG. 7A, showing another view of the semiconductor structure at this particular point in one example semiconductor fabrication process of an embodiment of the present disclosure. The cross-sectional view shown in FIG. 7D is illustrated, right to left in the plane of the drawing sheet, extending in the first direction (D1) 709 along an axis of the repeating iterations of alternating layers of first dielectric material 739 and Si material 732 wrapped with a gate dielectric material 742. The gate dielectric material 742 may be conformally deposited fully around every surface of the Si material 732, to form gate all around (GAA) gate structures, at the channels of the access device regions. The first conductive material 777 may fill the spaces adjacent the bridged Si material 732. The Si material 732 may be surrounded by first conductive material 777 formed on the gate dielectric material 742. The first conductive material 777 may be conformally deposited fully around every surface of the Si material 732, to form gate all around (GAA) gate structures, at the channels of the access device regions.

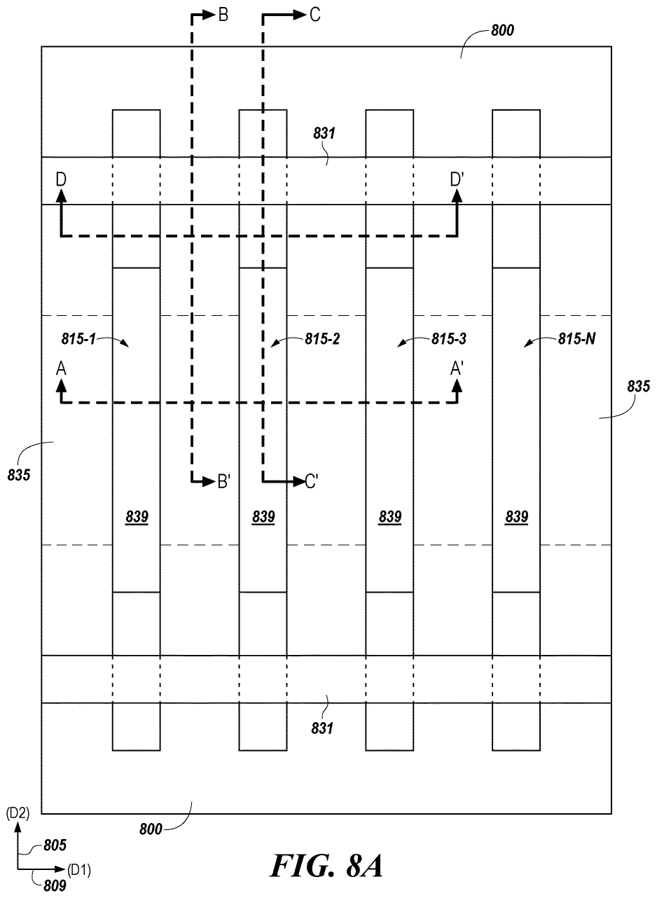

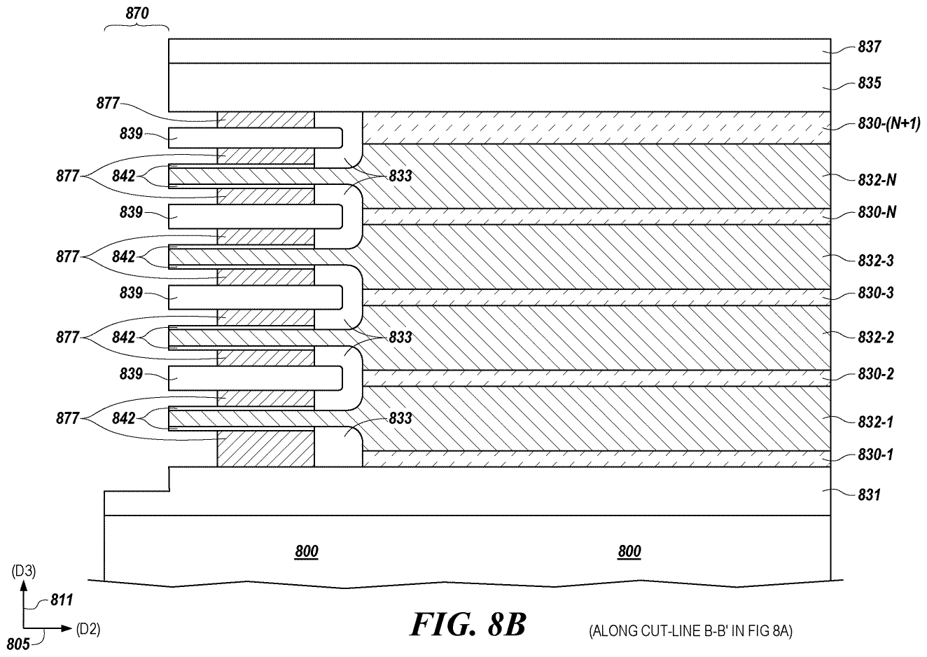

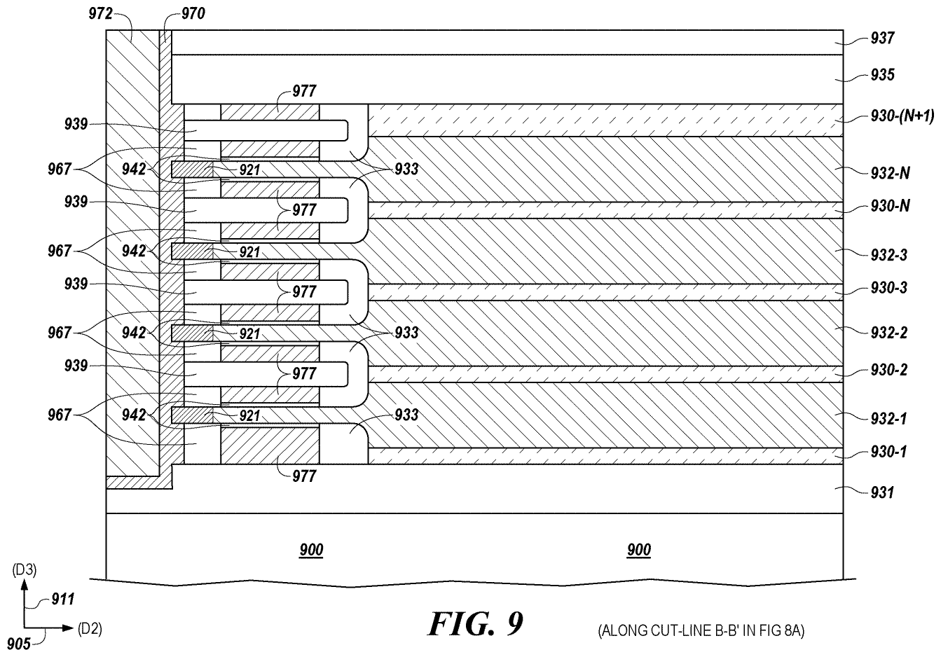

FIGS. 8A to 8B illustrate an example method, at another stage of a semiconductor fabrication process, for vertical three-dimensional (3D) memory with a multiplexer, in accordance with a number of embodiments of the present disclosure. FIG. 8A illustrates a top-down view of a semiconductor structure, at a particular point in time, in a semiconductor fabrication process, according to one or more embodiments. In the example embodiment of FIG. 8A, the method comprises using a photolithographic process to pattern the photolithographic mask 835. The first conductive material 877 may have been deposited above the vertical openings 831 and is now recessed.

FIG. 8B illustrates a cross sectional view, taken along cut-line B-B′ in FIG. 8A, showing another view of the semiconductor structure at this particular point in one example semiconductor fabrication process of an embodiment of the present disclosure. The cross-sectional view shown in FIG. 8B is illustrated extending in the second horizontal direction (D2) 805, left and right along the plane of the drawing sheet, along an axis of the repeating iterations of alternating layers of the SiGe material 830 and the Si material 832.

A first conductive material 877 was deposited on the gate dielectric material and formed around the Si material 832, recessed back, to form gate all around (GAA) structure opposing channel regions of the Si material 832. The first conductive material 877, formed on the gate dielectric material 842, may be recessed and etched away from the vertical opening 870.

In some embodiments, the first conductive material 877 may be etched using an atomic layer etching (ALE) process. In some embodiments, the first conductive material 877 may be etched using an isotropic etch process. The first conductive material 877 may be selectively etched leaving the oxide material 842 covering the Si material 832 and the first dielectric material 839 intact. The first conductive material 877 may be selectively etched in the second direction, in the continuous second horizontal openings, a third distance (DIST 3) in a range of twenty (20) to fifty (50) nanometers (nm) back from the third vertical opening 870. The first conductive material 877 may be selectively etched around the epitaxially grown, single crystalline silicon (Si) material 832 back into the continuous second horizontal openings extending in the first horizontal direction.

FIG. 9 illustrates a cross sectional view, taken along cut-line B-B′ in FIG. 8A, showing another view of the semiconductor structure at this particular point in one example semiconductor fabrication process, for vertical three-dimensional (3D) memory with a multiplexer, in accordance with a number of embodiments of the present disclosure. FIG. 9 illustrates a cross sectional view, taken along cut-line B-B′ in FIG. 8A, showing another view of the semiconductor structure at this particular point in one example semiconductor fabrication process, for vertical three-dimensional (3D) memory with a multiplexer, in accordance with a number of embodiments of the present disclosure. The cross-sectional view shown in FIG. 9 is illustrated extending in the second horizontal direction (D2) 905, left and right along the plane of the drawing sheet, along an axis of the repeating iterations of alternating layers of the SiGe material 930 and the Si material 932.

As shown in FIG. 9, another dielectric material 967 may be deposited in the vertical openings 931 to fill the vertical openings 931 and the first horizontal openings up to the first conductive material 977. As further shown in FIG. 9, the dielectric material 967 may be recessed into the first horizontal opening to conductively isolate the first conductive material 977, above and below the single crystalline silicon (Si) material 832, and to remove the dielectric material 967 from the first vertical openings 931. The dielectric material 967 may be the same as the first or the second dielectric materials 839 in FIG. 8B or 933 in FIG. 9, or may be a different, third selectively etchable dielectric material such and SiCN, etc. The dielectric material 967 may be conformally deposited using a chemical vapor deposition (CVD) process, plasma enhanced CVD (PECVD), atomic layer deposition (ALD), or other suitable deposition process.

At this point in an example fabrication sequence, first source/drain regions 921 may be formed at the ends of the single crystalline silicon (Si) 932 adjacent the first vertical openings 931. In some embodiments, the first source/drain regions 931 may be formed by gas phase doping exposed surfaces of the ends of the single crystalline silicon (Si) 932 adjacent the first vertical openings 931. Embodiments, however, are not limited to this example and other suitable techniques may be used.

FIG. 9 further illustrates an example embodiment of a vertical digit line formed by the combination of second conductive material 970 and third conductive material 972 formed within the first vertical openings (e.g., vertical openings 870 in FIG. 8). In one example, a second conductive material 970 may be conformally formed in the vertical openings. The second conductive material 970 may be formed from a conformal deposition of a highly doped polysilicon material 970. In one example, the dopant can include a high concentration n-type dopant. In a further example, the polysilicon may first be deposited and then a high concentration of n-type dopant may be implanted therein from the second conductive material 970. One example of forming the second conductive material 970 includes conformally depositing a highly phosphorus (P) doped (n+-type dopant) poly-silicon germanium (SiGe) material into the first vertical openings for the second conductive material 970.

A third conductive material 972 may be deposited into the first vertical opening on the second conductive material 970 to fill the vertical opening as shown in FIG. 9. In some embodiments, the third conductive material 972 may comprise one or more of a doped semiconductor material, e.g., doped silicon, doped germanium, etc., a conductive metal nitride, e.g., titanium nitride, tantalum nitride, etc., a metal, e.g., tungsten (W), titanium (Ti), tantalum (Ta), ruthenium (Ru), cobalt (Co), molybdenum (Mo), etc., and/or a metal-semiconductor compound, e.g., tungsten silicide, cobalt silicide, titanium silicide, etc., and/or some other combination thereof. The third conductive material 972 coupled to the second conductive material 970 may be formed vertically adjacent first source/drain regions to horizontal access devices to form vertical digit lines.

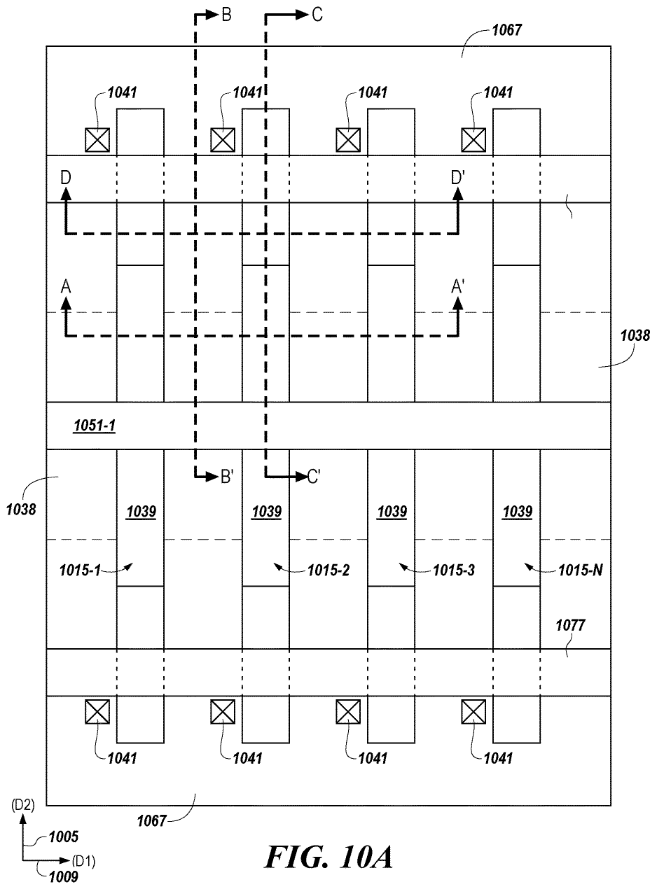

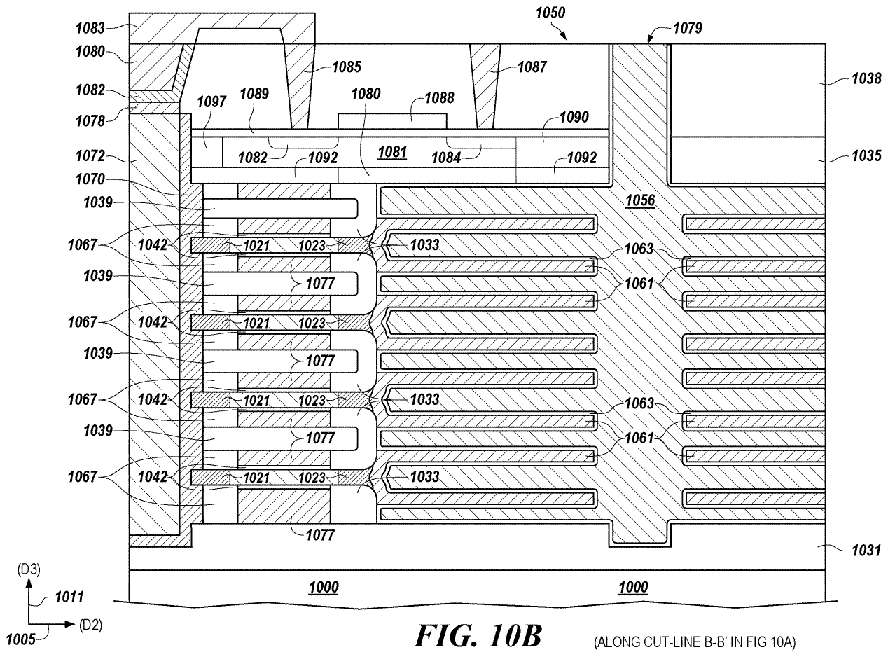

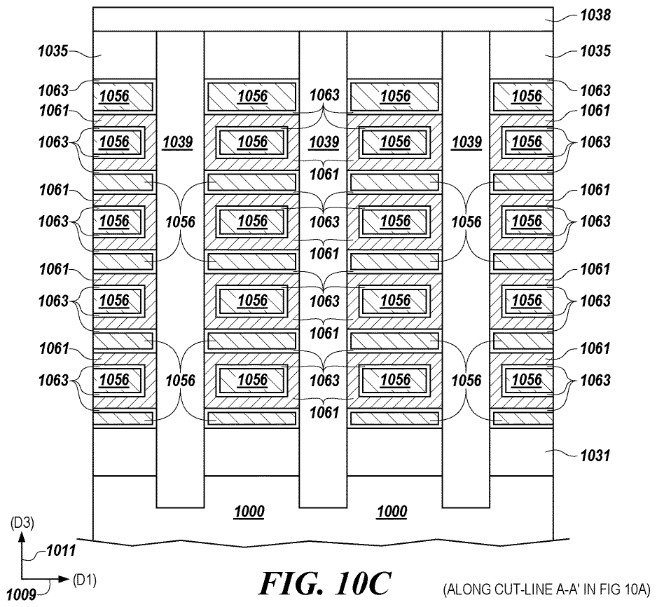

FIGS. 10A to 10C illustrates an example method, at another stage of a semiconductor fabrication process, for vertical three-dimensional (3D) memory with a multiplexer, in accordance with a number of embodiments of the present disclosure. As illustrated in FIG. 10A, a second vertical opening 1051 can be formed in a storage node region 1050 through the vertical stack and extending predominantly in the first horizontal direction (D1) 1009. The vertical opening 1051 can be formed from one or more etchant processes to expose sidewalls in the repeating iterations of alternating layers of alternating silicon germanium (SiGe), 430-1, 430-2, . . . , 430-N layers and epitaxially grown, single crystalline silicon (Si) material, 432-1, 432-2, . . . , 432-N layers, shown in FIG. 4 in the vertical stack in order to form storage nodes.

FIG. 10B is a cross sectional view, taken along cut-line B-B′ in FIG. 10A, showing another view of the semiconductor structure at a particular time in the semiconductor fabrication process. In FIG. 10B, the one or more etchant processes can be utilized to form the storage node region 1050. The storage node region 1050 can include storage nodes (e.g., horizontally oriented capacitor cells) having the first electrodes 1061, e.g., bottom electrodes, to be coupled to source/drain regions of horizontal access devices, and second electrodes 1056, e.g., top electrodes, to be coupled to a common electrode plane such as a ground plane, and separated from the first electrodes 1061 by a dielectric 1063. The storage nodes are shown formed in a second horizontal opening 1079, extending in second direction (D2) 1005, left and right in the plane of the drawing sheet, a third distance from the vertical opening formed in the vertical stack and along an axis of orientation of the horizontal access devices and horizontal storage nodes of the arrays of vertically stacked memory cells of the three-dimensional (3D) memory.

In some embodiments, the epitaxial grown, single crystalline silicon (Si) in the exposed sidewalls, e.g., in the repeating iterations of alternating layers of alternating silicon germanium (SiGe), 430-1, 430-2, . . . , 430-N layers and epitaxially grown, single crystalline silicon (Si) material, 432-1, 432-2, . . . , 432-N layers, shown in FIG. 4, can be selectively etched to create second horizontal openings 1079 to expose a second source/drain region 1023 of the horizontal access devices to couple the first electrodes 1061. At this point in an example fabrication sequence, second source/drain regions 1023 may be formed in the ends of the single crystalline silicon (Si) 1032 within the second horizontal openings 1079 before formation of the first electrodes 1061. In some embodiments, the second source/drain regions 1031 may be formed by gas phase doping exposed surfaces of the single crystalline silicon (Si) 1032 within the second horizontal openings 1079. Embodiments, however, are not limited to this example and other suitable techniques may be used.

In FIG. 10B, a neighboring, horizontal access line 1077 is illustrated adjacent the second dielectric material 1033, with a portion of the first conductive material 1077 located above the Si material 1032, and a portion of the first conductive material 1077 located below the Si material 1032 extending in a direction inward and outward from the plane and orientation of the drawing sheet.

Additionally, as illustrated in FIG. 10B, the dielectric material 1067 isolates the first conductive material from the from the digit line 1070/1072 coupled to the first source/drain regions 1021 of the horizontal access devices.

A multiplexer device can be formed on the 3D DRAM array in a multiplexer silicon layer 1035. The multiplexer device can include first source/drain region 1082 and second source/drain region 1084. A channel region for the multiplexer can be between the first source/drain region 1082 and a second source/drain region 1084 and the multiplexer device can include body region 1081. A multiplexer word line 1088 can be formed over a gate material 1089 and over the channel region of the multiplexer device. The multiplexer word line 1088 can be biased to turn the multiplexer device on and off.

The multiplexer device can include a conductive contact 1080 (e.g., body contact region) that contacts the body region 1081. Conductive contact 1080 can be coupled to a voltage source to provide a voltage potential to bias the multiplexer device and reduce and/or eliminate floating body effects (FBE). The conductive contact 1080 can be coupled to a voltage source to provide a voltage potential to bias the multiplexer device and control the threshold voltage for activating and/or deactivating the multiplexer device. The conductive contact 1080 can be coupled to a voltage source to provide a voltage potential to bias the multiplexer device and reduce and/or eliminate plate disturb from the upper electrode of the storage nodes in the array of memory cells. The conductive contact 1080 can separate the body region 1081 from the vertical stack, including an access device region and a storage node region. The conductive contact 1080 can be separated from electrode 1056 and from the digit line 1070 by dielectric material 1092, the body region 1081 can be separated from the digit line 1070 by dielectric material 1097, and the body region 1081 can be separate from the electrode 1056 by dielectric 1090.

A digit line contacts 1083 and 1085 and can be formed on source/drain region 1082 to couple the multiplexer device to digit line 1072. Digit line contact 1087 can be formed on source/drain region 1084. Digit line contact 1087 can be coupled to a global digit line (not shown) to couple the multiplexer device to logic circuitry used to access the multiplexer device and the array of memory cells.

FIG. 10C is a cross sectional view, taken along cut-line A-A′ in FIG. 10A, showing another view of the semiconductor structure at a particular time in the semiconductor fabrication process. The cross-sectional view shown in FIG. 10C is in the storage node region, away from the plurality of separate, horizontal access lines 1077, and shows repeating iterations of alternating layers horizontally oriented capacitor cells having second electrodes 1056, e.g., top electrodes which may be connected to a common node, separated by from first electrodes 1061, e.g., bottom cell contact electrodes, by a cell dielectric material 1063. In the example embodiment of FIG. 10C, the first electrodes 1061, e.g., bottom electrodes, to be coupled to source/drain regions of horizontal access devices, and second electrodes 1056 are illustrated separated by a cell dielectric material 1063 extending into and out of the plane of the drawing sheet in second direction (D2) and along an axis of orientation of the horizontal access devices and horizontal storage nodes of the arrays of vertically stacked memory cells of the 3D memory. In FIG. 10C, the first dielectric material 1039 is shown separating the space between neighboring horizontally oriented access devices and horizontally oriented storage nodes.

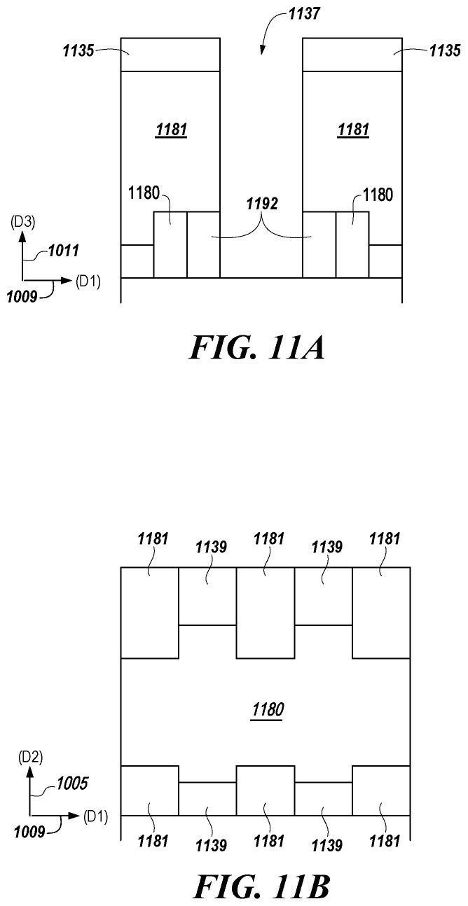

FIGS. 11A to 11B illustrate an example method, at another stage of a semiconductor fabrication process, for vertical three-dimensional (3D) memory with a multiplexer, in accordance with a number of embodiments of the present disclosure. In FIG. 11A, a cross sectional side view of the multiplexer silicon region 1135 along directions D1 1009 and D3 1011 is illustrated for an example method of forming the multiplexer. A vertical opening 1137 can be formed in the multiplexer silicon region 1135 in between multiplexer devices and a horizontal opening can be formed in the multiplexer silicon region 1135 and in a dielectric region separating the multiplexer silicon region 1135 from the vertical stack. The conductive contact material 1180 and the dielectric material 1192 can be formed in the horizontal opening.

In FIG. 11B, a cross sectional side view along the conductive contact 1180 along directions D1 1009 and D2 1005 is illustrated. The body region 1181 for each multiplexer device is separated by dielectric material 1139. The conductive contact 1180 can be continuous in the D1 direction 1009 and contacts the above region above the storage node region.

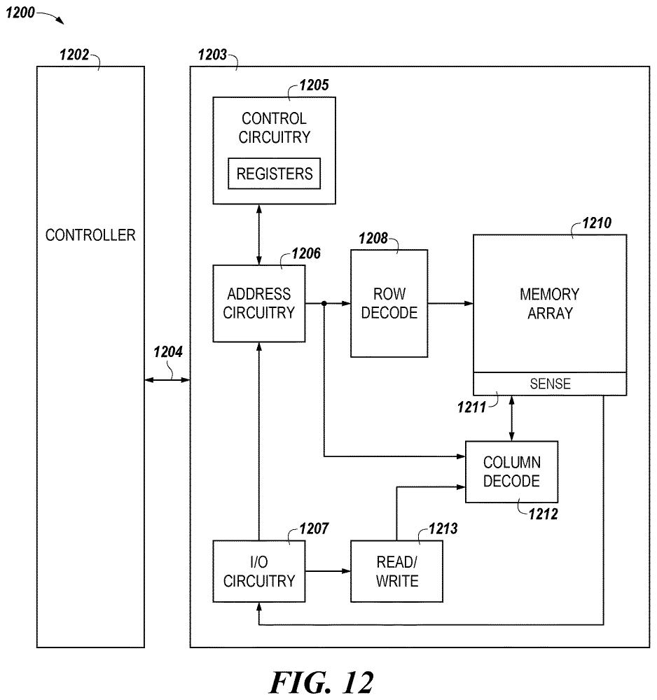

FIG. 12 is a block diagram of an apparatus in the form of a computing system 1200 including a memory device 1203 in accordance with a number of embodiments of the present disclosure. As used herein, a memory device 1203, a memory array 1210, and/or a host 1202, for example, might also be separately considered an “apparatus.” According to embodiments, the memory device 1203 may comprise at least one memory array 1210 with a memory cell formed having a digit line and body contact, according to the embodiments described herein.

In this example, system 1200 includes a host 1202 coupled to memory device 1203 via an interface 1204. The computing system 1200 can be a personal laptop computer, a desktop computer, a digital camera, a mobile telephone, a memory card reader, or an Internet-of-Things (IoT) enabled device, among various other types of systems. Host 1202 can include a number of processing resources (e.g., one or more processors, microprocessors, or some other type of controlling circuitry) capable of accessing memory 1203. The system 1200 can include separate integrated circuits, or both the host 1202 and the memory device 1203 can be on the same integrated circuit. For example, the host 1202 may be a system controller of a memory system comprising multiple memory devices 1203, with the system controller 1202 providing access to the respective memory devices 2403 by another processing resource such as a central processing unit (CPU).

In the example shown in FIG. 12, the host 1202 is responsible for executing an operating system (OS) and/or various applications (e.g., processes) that can be loaded thereto (e.g., from memory device 1203 via controller 1202). The OS and/or various applications can be loaded from the memory device 1203 by providing access commands from the host 1202 to the memory device 1203 to access the data comprising the OS and/or the various applications. The host 1202 can also access data utilized by the OS and/or various applications by providing access commands to the memory device 1203 to retrieve said data utilized in the execution of the OS and/or the various applications.

For clarity, the system 1200 has been simplified to focus on features with particular relevance to the present disclosure. The memory array 1210 can be a 3D DRAM array comprising at least one memory cell having a vertical digit line and enhanced contacts to the vertical digit line in vertical three-dimensional (3D) memory, in accordance with a number of embodiments of the present disclosure. For example, the memory array 1210 can be an unshielded DL 4F2 array such as a 3D-DRAM memory array. The array 1210 can comprise memory cells arranged in rows coupled by word lines (which may be referred to herein as access lines or select lines) and columns coupled by digit lines (which may be referred to herein as sense lines or data lines). Although a single array 1210 is shown in FIG. 12, embodiments are not so limited. For instance, memory device 1203 may include a number of arrays 1210 (e.g., a number of banks of DRAM cells).

The memory device 1203 includes address circuitry 1206 to latch address signals provided over an interface 1204. The interface can include, for example, a physical interface employing a suitable protocol (e.g., a data bus, an address bus, and a command bus, or a combined data/address/command bus). Such protocol may be custom or proprietary, or the interface 1204 may employ a standardized protocol, such as Peripheral Component Interconnect Express (PCIe), Gen-Z, CCIX, or the like. Address signals are received and decoded by a row decoder 1208 and a column decoder 1212 to access the memory array 1210. Data can be read from memory array 1210 by sensing voltage and/or current changes on the sense lines using sensing circuitry 1211. The sensing circuitry 1211 can comprise, for example, sense amplifiers that can read and latch a page (e.g., row) of data from the memory array 1210. The I/O circuitry 1207 can be used for bi-directional data communication with the host 1202 over the interface 1204. The read/write circuitry 1213 is used to write data to the memory array 1210 or read data from the memory array 1210. As an example, the circuitry 1213 can comprise various drivers, latch circuitry, etc.

Control circuitry 1205 decodes signals provided by the host 1202. The signals can be commands provided by the host 1202. These signals can include chip enable signals, write enable signals, and address latch signals that are used to control operations performed on the memory array 1210, including data read operations, data write operations, and data erase operations. In various embodiments, the control circuitry 1205 is responsible for executing instructions from the host 1202. The control circuitry 1205 can comprise a state machine, a sequencer, and/or some other type of control circuitry, which may be implemented in the form of hardware, firmware, or software, or any combination of the three. In some examples, the host 1202 can be a controller external to the memory device 1203. For example, the host 1202 can be a memory controller which is coupled to a processing resource of a computing device.

The term semiconductor can refer to, for example, a material, a wafer, or a substrate, and includes any base semiconductor structure. “Semiconductor” is to be understood as including silicon-on-sapphire (SOS) technology, silicon-on-insulator (SOI) technology, thin-film-transistor (TFT) technology, doped and undoped semiconductors, epitaxial silicon supported by a base semiconductor structure, as well as other semiconductor structures. Furthermore, when reference is made to a semiconductor in the preceding description, previous process steps may have been utilized to form regions/junctions in the base semiconductor structure, and the term semiconductor can include the underlying materials containing such regions/junctions.

The figures herein follow a numbering convention in which the first digit or digits correspond to the drawing figure number and the remaining digits identify an element or component in the drawing. Similar (e.g., the same) elements or components between different figures may be identified by the use of similar digits. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate the embodiments of the present disclosure and should not be taken in a limiting sense.

As used herein, “a number of” or a “quantity of” something can refer to one or more of such things. For example, a number of or a quantity of memory cells can refer to one or more memory cells. A “plurality” of something intends two or more. As used herein, multiple acts being performed concurrently refers to acts overlapping, at least in part, over a particular time period. As used herein, the term “coupled” may include electrically coupled, directly coupled, and/or directly connected with no intervening elements (e.g., by direct physical contact), indirectly coupled and/or connected with intervening elements, or wirelessly coupled. The term coupled may further include two or more elements that co-operate or interact with each other (e.g., as in a cause and effect relationship). An element coupled between two elements can be between the two elements and coupled to each of the two elements.

It should be recognized the term vertical accounts for variations from “exactly” vertical due to routine manufacturing, measuring, and/or assembly variations and that one of ordinary skill in the art would know what is meant by the term “perpendicular.” For example, the vertical can correspond to the z-direction. As used herein, when a particular element is “adjacent to” an other element, the particular element can cover the other element, can be over the other element or lateral to the other element and/or can be in direct physical contact the other element. Lateral to may refer to the horizontal direction (e.g., the y-direction or the x-direction) that may be perpendicular to the z-direction, for example.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

What is claimed is:

1. A method of forming a three dimensional (3D) memory device, comprising:
forming a vertical stack having an array of memory cells including horizontally oriented access devices and horizontally oriented storage nodes; and
forming a multiplexer device on the vertical stack, wherein the multiplexer device includes a first source/drain region coupled to a first digit line of the vertical stack and a second source/drain region coupled to a second digit line and wherein the multiplexer device includes a conductive contact coupled to a body region of the multiplexer device between the first source/drain region of the multiplexer device and a storage node region of the vertical stack.

2. The method of claim 1, wherein forming the multiplexer device includes forming a multiplexer word line coupled to a gate of the multiplexer device and configured to activate and deactivate the multiplexer device.

3. The method of claim 1, further including coupling the conductive contact to a voltage source.

4. The method of claim 1, wherein the first digit line is a local digit line of the vertical stack having the array of memory cells and the second digit line is a global digit line connected to a plurality of vertically stacked arrays of memory cells.

5. The method of claim 1, further including forming a first dielectric portion between the second source/drain region and an access device region of the vertical stack.

6. The method of claim 1, further including forming a second dielectric portion between the conductive contact and an electrode of the horizontally oriented storage nodes.

7. The method of claim 1, wherein the multiplexer device is configured as a multiplexer for a number of memory cells coupled to the first digit line in the vertical stack having the array of memory cells.

8. The method of claim 1, wherein forming the multiplexer device includes forming the first source/drain region over an access device region of the vertical stack having the array of memory cells.

9. The method of claim 1, wherein forming the multiplexer device includes forming the second source/drain region over a storage node region of the vertical stack having the array of memory cells.

10. An apparatus, comprising:
an array of vertically stacked memory cells, the array having horizontally oriented access devices and storage nodes;
a multiplexer device formed on the array of vertically stacked memory cells, wherein the multiplexer device includes a conductive contact coupled to a body region of the multiplexer device between a first source/drain region of the multiplexer device and a storage node region of the array of vertically stacked memory cells;
a local digit line coupled to the first source/drain region of the multiplexer device and to the access devices of the array of vertically stack memory cells; and
a global digit line coupled to a second source/drain region of the multiplexer device and to logic components for accessing the array of vertically stacked memory cells.

11. The apparatus of claim 10, wherein the multiplexer device includes a multiplexer word line coupled to a gate of the multiplexer device and configured to activate and deactivate the multiplexer device.

12. The apparatus of claim 10, wherein the conductive contact is coupled to a voltage source.

13. The apparatus of claim 10, wherein a first dielectric portion is between the second source/drain region and the conductive contact.

14. The apparatus of claim 10, wherein a second dielectric portion is between the conductive contact and an electrode of the horizontally oriented storage nodes.

15. The apparatus of claim 10, wherein the multiplexer device is configured as a multiplexer for a number of memory cells coupled to the local digit line.

16. The apparatus of claim 10, wherein the first source/drain region is formed over an access device region of the array of vertically stacked memory cells and the second source/drain region is formed over a storage node region of the array of vertically stacked memory cells.

17. An apparatus, comprising:
an array of vertically stacked memory cells, the array having horizontally oriented access devices and storage nodes; and
a multiplexer device formed on the array of vertically stacked memory cells, wherein the multiplexer device includes a conductive contact coupled to a body region of the multiplexer device between a first source/drain region of the multiplexer device and a storage node region of the array of vertically stacked memory cells and wherein the multiplexer device includes a word line configured to activate and deactivate the multiplexer device.

18. The apparatus of claim 17, wherein the apparatus includes a digit line coupled to a second source/drain region of the multiplexer device.

19. The apparatus of claim 18, wherein the digit line is a local digit line of the array of vertically stacked memory cells.

20. The apparatus of claim 17, wherein the apparatus includes a digit line contact coupled to the first source/drain region of the multiplexer device and wherein the digit line contact is coupled to a global digit line.
